(19) United States
(12) Patent Application Publication
(10) Pub. No.: US 2026/0076110 A1
(43) Pub. Date: Mar. 12, 2026

(54) HYBRID ATOMIC LAYER DEPOSITION

(71) Applicant: Lam Research Corporation, Fremont, CA (US)

(72) Inventors: Awnish Gupta, Hillsboro, OR (US); Bart J. van Schravendijk, Palo Alto, CA (US); Jon Henri, West Linn, OR (US); Oksana Savchak, Tualatin, OR (US); Fengyan Wei, Lake Oswego, OR (US); Easwar Srinivasan, Portland, OR (US); Aaron Blake Miller, West Linn, OR (US); Dustin Zachary Austin, Tigard, OR (US)

(21) Appl. No.: 18/868,708

(22) PCT Filed: May 24, 2023
(86) PCT No.: PCT/US2023/023418

§ 371 Date: Nov. 22, 2024

Related U.S. Application Data
(60) Provisional application No. 63/365,260, filed on May 24, 2022.
(60) Provisional application No. 63/365,473, filed on May 27, 2022.
(60) Provisional application No. 63/366,950, filed on Jun. 24, 2022.

(51) Int. Cl. H01L 21/02; C23C 16/34; C23C 16/44; C23C 16/455; C23C 16/50; C23C 16/56; H01J 37/32

(52) U.S. Cl. CPC H10P 14/6336; C23C 16/345; C23C 16/4404; C23C 16/45542; C23C 16/50; C23C 16/56; H01J 37/3244; H10P 14/69433; H01J 37/32357; H01J 2237/332

(57) ABSTRACT

Methods and apparatuses for depositing silicon nitride using a hybrid atomic layer deposition technique are provided. Methods and apparatuses for forming halogen-free undercoats in a process chamber using a halogen-free aminosilane precursor are provided. Methods and apparatuses for forming silicon oxynitride using a single-wafer chamber are provided herein. Methods and apparatus also include forming graded silicon oxynitride using cyclic deposition and in-situ nitridation and/or oxidation techniques.

### INCORPORATION BY REFERENCE

An Application Data Sheet is filed concurrently with this specification as part of this application. Each application to which this application claims benefit or priority as identified in the concurrently filed Application Data Sheet is incorporated by reference herein in its entirety and for all purposes.

### BACKGROUND

Semiconductor fabrication processes involve deposition of silicon-containing materials, including silicon nitride materials on low-k dielectric materials. It is challenging to reduce damage to the low-k dielectric during deposition of silicon nitride while forming high quality silicon nitride.

Semiconductor processing methods may involve using various chemistries, some of which may interact with the material of chamber parts within the process chamber during processing. As a result, chamber parts may be protected by first forming an undercoat film on the parts prior to processing semiconductor wafers therein. Various chamber parts may withstand different conditions during processing and may involve undercoat deposition methods that vary from part to part.

Semiconductor fabrication processes involve deposition of silicon-containing materials, including graded films having graded amounts of oxygen and nitrogen molecules within the film. It is challenging to control the gradient of oxygen or nitridation of a silicon-containing material using certain methods and apparatuses.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method for processing substrates, the method including: providing a substrate having a feature thereon; exposing the substrate to a silicon-containing precursor in vapor phase for a duration sufficient to adsorb at least some of the silicon-containing precursor onto a surface of the substrate to form an adsorbed silicon-containing precursor; exposing the substrate to a first nitrogen-containing gas in a plasma-free environment; and exposing the substrate to a plasma generated from igniting a second nitrogen-containing gas to form silicon nitride on the surface of the substrate. In some embodiments, exposing the substrate to a first nitrogen-containing gas in a plasma-free environment is performed after exposing the substrate to the silicon-containing precursor in vapor phase. In some embodiments, exposing the substrate to a plasma generated from igniting a second nitrogen-containing gas to form silicon nitride on the surface of the substrate is performed after exposing the substrate to the first nitrogen-containing gas in the plasma-free environment.

In various embodiments, the plasma including radical species selected from the group consisting of nitrogen radicals, hydrogen radicals, and nitrogen hydrogen radicals.

In various embodiments, the first nitrogen-containing gas includes ammonia (NH₃) gas.

In various embodiments, exposing the substrate to the first nitrogen-containing gas in the plasma-free environment further includes exposing the substrate to hydrogen gas.

In various embodiments, the second nitrogen-containing gas includes two or more gases.

In various embodiments, the second nitrogen-containing gas is one or more of nitrogen (N₂) gas and ammonia (NH₃) gas.

In various embodiments, the silicon-containing precursor is a halogen-containing precursor. For example, in some embodiments, the silicon-containing precursor is one of dichlorosilane (DCS), hexachlorodisilane (HCDS), and tetrachlorosilane.

In various embodiments, the plasma is generated remotely.

In various embodiments, at least one of the first nitrogen-containing gas and second nitrogen-containing gas is diluted with nitrogen (N₂) gas.

In various embodiments, exposing the substrate to the silicon-containing precursor in vapor phase and exposing the substrate to a first nitrogen-containing gas in a plasma-free environment are performed in temporally separated pulses for one or more cycles prior to exposing the substrate to the plasma generated from igniting the second nitrogen-containing gas.

In various embodiments, the chamber pressure during at least one of the exposing the substrate to the silicon-containing precursor in vapor phase and the exposing the substrate to a first nitrogen-containing gas in a plasma-free environment is about 5 Torr to about 25 Torr.

In various embodiments, the chamber pressure during the plasma generated from igniting the second nitrogen-containing gas is about 1 Torr to about 10 Torr.

In various embodiments, the chamber pressure during the plasma generated from igniting the second nitrogen-containing gas is at least about 40% lower than chamber pressure during at least one of the exposing the substrate to the silicon-containing precursor in vapor phase and the exposing the substrate to a first nitrogen-containing gas in a plasma-free environment.

In various embodiments, exposing the substrate to the plasma generated from igniting the second nitrogen-containing gas includes exposing the substrate to hydrogen gas.

In various embodiments, exposing the substrate to the plasma generated from igniting the second nitrogen-containing gas is performed for a duration of about 1 second to about 30 seconds.

In various embodiments, exposing the substrate to the silicon-containing precursor in vapor phase, exposing the substrate to the first nitrogen-containing gas in the plasma-free environment, and exposing the substrate to the plasma generated from igniting the second nitrogen-containing gas are performed without breaking vacuum.

In various embodiments, exposing the substrate to the silicon-containing precursor in vapor phase, exposing the substrate to the first nitrogen-containing gas in the plasma-free environment, and exposing the substrate to the plasma generated from igniting the second nitrogen-containing gas are performed in the same chamber.

In various embodiments, at least one or more of exposing the substrate to the silicon-containing precursor in vapor phase, exposing the substrate to the first nitrogen-containing gas in the plasma-free environment, and exposing the substrate to the plasma generated from igniting the second nitrogen-containing gas are performed in a single-wafer chamber.

In any of the above embodiments, the method may also include purging a process chamber housing the substrate before or after any one or more of exposing the substrate to the silicon-containing precursor, exposing the substrate to the first nitrogen-containing gas in the plasma-free environment, and exposing the substrate to the plasma generated from igniting the second nitrogen-containing gas.

In some embodiments, a chamber pressure of the process chamber is reduced during the purging. In any of the above embodiments, the substrate is heated to a temperature of at least about 500° C.

In certain embodiments, the method also includes exposing the formed silicon nitride to an in-situ nitridation or oxidation process to incorporate nitrogen or oxygen to form a second silicon-containing film. In certain embodiments, the method also includes prior to providing the substrate having the feature thereon, setting a temperature of one or more chamber components of a process chamber used to house substrates to at least about 650° C.; after setting the temperature to at least about 650° C., introducing a halogen-free aminosilane precursor to the process chamber; and introducing a nitrogen-containing reactant and igniting a plasma to form a silicon nitride undercoat on at least one of the one or more chamber components.

Another aspect involves an apparatus for processing substrates, the apparatus including: one or more process chambers, each process chamber including a chuck; one or more gas inlets into the process chambers and associated flow-control hardware; a plasma generator; and a controller having at least one processor and a memory, whereby the at least one processor and the memory are communicatively connected with one another, the at least one processor is at least operatively connected with the flow-control hardware, and the memory stores computer-executable instructions for controlling the at least one processor to at least control the flow-control hardware to: cause introduction of a silicon-containing precursor to the one or more process chambers for a duration sufficient to adsorb at least some of the silicon-containing precursor to adsorb to a surface of a substrate without igniting a plasma; cause introduction of a first nitrogen-containing gas without igniting a plasma; and cause generation of a plasma using a second nitrogen-containing gas to form silicon nitride.

In any of the above embodiments, the plasma generator is a remote plasma generator.

Another aspect involves a method for treating a process chamber having no substrate therein, the method including: setting a temperature of one or more chamber components of the process chamber to at least about 650° C.; after setting the temperature to at least about 650° C., introducing a halogen-free aminosilane precursor to the process chamber; and introducing a nitrogen-containing reactant and igniting a plasma to form a silicon nitride undercoat on at least one of the one or more chamber components.

In various embodiments, the method also includes, prior to setting the temperature of the one or more chamber components of the process chamber to at least about 650° C., cleaning at least one of the one or more chamber components at a temperature of about 400° C.

In some embodiments, the cleaning is performed at a chamber pressure of about 4 Torr to about 8 Torr.

In some embodiments, the cleaning includes flowing nitrogen gas and diverting aluminum fluoride to a pump. For example, in some embodiments, the nitrogen gas is flowed at a flow rate of about 10 slm to about 40 slm.

In various embodiments, the method also includes, after introducing the halogen-free aminosilane precursor and before introducing the nitrogen-containing reactant, purging the process chamber.

In various embodiments, the method also includes, after introducing the nitrogen-containing reactant, purging the process chamber.

In various embodiments, the method also includes, repeating introducing the halogen-free aminosilane precursor and introducing the nitrogen-containing reactant in cycles. In some embodiments, about 100 to about 5000 cycles are performed.

In various embodiments, the method also includes, the halogen-free aminosilane precursor has precursor has a formula of (R′)₄₋ₓSi(NR″₂)ₓ, where x is 1, 2, 3, or 4; and R′ is one of hydrogen, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, isocyano groups and substituted variations thereof; and R″ is one of hydrogen, aliphatic, heteroaliphatic, aromatic, heteroaromatic, or amino groups.

In various embodiments, the aminosilane precursor is one of diisopropylaminosilane, t-butylaminosilane, methylaminosilane, tert-butylsilanamine, bis(tertiarybutylamino) silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino) silane (DSBAS), bis(diethylamino) silane (BDEAS), and trisilylamine (N(SiH₃)₃).

In various embodiments, the one or more chamber components includes a pedestal.

In various embodiments, chamber pressure is constant during the introducing of the halogen-free aminosilane precursor and introducing of the nitrogen-containing reactant in cycles.

In various embodiments, the silicon nitride undercoat is deposited to a thickness of at least about 300 Å.

In various embodiments, the method includes, after forming the silicon nitride undercoat, processing one or more substrates in the process chamber using a halogen-containing gas.

Another aspect involves an apparatus for processing substrates, the apparatus including: one or more process chambers, each process chamber including a chuck; one or more gas inlets into the process chambers and associated flow-control hardware; and a controller having at least one processor and a memory, where the at least one processor and the memory are communicatively connected with one another, the at least one processor is at least operatively connected with the flow-control hardware, and the memory stores computer-executable instructions for controlling the at least one processor to at least control the flow-control hardware to: cause setting of a temperature one or more chamber components of the process chamber to at least about 650° C.; after causing setting of the temperature to at least about 650° C., cause introduction of a halogen-free aminosilane precursor to the process chamber; and cause introduction of a nitrogen-containing reactant and generation of a plasma to form a silicon nitride undercoat on at least one of the one or more chamber components.

In some embodiments, the memory also includes computer-executable instructions for, prior to causing setting of the temperature of the one or more chamber components of the process chamber to at least about 650° C., causing introduction of a nitrogen gas at a temperature of about 400° C. to pre-clean the process chamber.

One aspect involves a method for processing substrates, the method including: introducing a substrate having a feature; exposing the substrate to a silicon-containing precursor for a duration sufficient to adsorb at least some silicon-containing precursor to a surface of the substrate; exposing the substrate to a reactant species for forming a first silicon-containing film; and exposing the first silicon-containing film to an in-situ nitridation or oxidation process to incorporate nitrogen or oxygen to form a second silicon-containing film.

In various embodiments, the in-situ nitridation or oxidation process converts the first silicon-containing film to the second silicon-containing film.

In various embodiments, the first silicon-containing film is silicon oxide. For example, in some embodiments, the silicon oxide has an atomic ratio of silicon to oxygen of about 33.5:66.5.

In various embodiments, the first silicon-containing film is silicon nitride. For example, in some embodiments, the silicon nitride has an atomic ratio of silicon to nitrogen of about 43:57.

In various embodiments, the second silicon-containing film is silicon oxynitride.

In various embodiments, the second silicon-containing film is a graded film.

In various embodiments, the second silicon-containing film is a graded silicon oxynitride film.

In various embodiments, the exposing the substrate to the silicon-containing precursor and the exposing the substrate to the reactant species is performed in cycles. In some embodiments, the in-situ nitridation or oxidation process is performed every n cycles, where n is about 1 to about 100.

In various embodiments, the silicon-containing precursor is a halogen-containing silicon-containing precursor. In some embodiments, the halogen-containing silicon-containing precursor is dichlorosilane.

In various embodiments, the silicon-containing precursor is an aminosilane. In some embodiments, the aminosilane is diisopropylamino silane (DIPAS).

In various embodiments, the silicon-containing precursor is diluted with nitrogen gas.

In various embodiments, the exposing the substrate to the silicon-containing precursor, the exposing the substrate to the reactant species, and the exposing the first silicon-containing film to the in-situ nitridation or oxidation process are performed in the same process chamber.

In various embodiments, exposing the substrate to the reactant species includes exposing the substrate to a first reactant gas without a plasma followed by exposing the substrate to a plasma generated by igniting a second reactant gas.

In various embodiments, the exposing the substrate to the reactant species includes flowing a mixture of oxygen and hydrogen gas in a plasma-free environment.

In various embodiments, the exposing the substrate to the reactant species includes generating a plasma from oxygen gas, hydrogen gas, or a mixture of oxygen and hydrogen gas.

In various embodiments, the reactant species is an oxygen-containing species. In some embodiments, the oxygen-containing species is one of oxygen, carbon dioxide, carbon monoxide, ozone, hydrogen peroxide, and plasmas thereof.

In various embodiments, exposing the substrate to the reactant species includes flowing a nitrogen-containing gas in a plasma-free environment.

In various embodiments, the reactant species is a nitrogen-containing species. For example, in some embodiments, the nitrogen-containing species is one of ammonia, nitrogen, nitrous oxide, nitric oxide, and plasmas thereof.

In various embodiments, the substrate is introduced to a process chamber set to a chamber pressure of about 5 Torr to about 25 Torr.

In various embodiments, the silicon-containing precursor is introduced using a flow rate of about 100 sccm to about 2000 sccm.

In various embodiments, the exposing the substrate to the silicon-containing precursor is performed for a duration of about 0.1 second to about 10 seconds.

In various embodiments, the silicon-containing precursor is flowed with a dilution gas having a flow rate of about 500 sccm to about 2000 sccm.

In various embodiments, the reactant species is flowed using a flow rate of about 100 sccm to about 10000 sccm.

In various embodiments, the reactant species is flowed using a flow rate of about 100 sccm to about 5000 sccm.

In various embodiments, the reactant species includes a mixture of oxygen and hydrogen. In some embodiments, the oxygen is flowed at a flow rate of about 100 sccm to about 5000 sccm and the hydrogen is flowed at a flow rate of about 0 sccm to about 5000 sccm.

In various embodiments, the reactant species is flowed using a flow rate of about 2000 sccm to about 10000 sccm.

In some embodiments, the reactant species includes a mixture of ammonia and hydrogen. In various embodiments, ammonia is flowed at a flow rate of about 2000 sccm to about 10000 sccm and the hydrogen is flowed at a flow rate of about 0 sccm to about 10000 sccm.

In various embodiments and in any of the above described embodiments, the silicon oxide film is conformal.

In various embodiments and in any of the above described embodiments, the method also includes purging after exposing the substrate to the silicon-containing precursor and before exposing the substrate to the reactant species.

In various embodiments and in any of the above described embodiments, the method also includes purging after exposing the surface of the substrate to the in-situ oxidation or nitridation.

In various embodiments and in any of the above described embodiments, the second silicon-containing film is a silicon oxynitride film formed as a tunneling layer in a 3D-NAND structure.

Another aspect involves an apparatus for processing substrates, the apparatus including: one or more process chambers, each process chamber including a chuck; one or more gas inlets into the process chambers and associated flow-control hardware; and a controller having at least one processor and a memory, whereby the at least one processor and the memory are communicatively connected with one another, the at least one processor is at least operatively connected with the flow-control hardware, and the memory stores computer-executable instructions for controlling the at least one processor to at least control the flow-control hardware to: cause introduction of a silicon-containing precursor to the one or more process chambers for a duration sufficient to adsorb at least some of the silicon-containing precursor to adsorb to a surface of a substrate; cause introduction of an oxygen-containing or nitrogen-containing gas; optionally cause generation of a plasma by igniting the oxygen-containing or nitrogen-containing gas; and cause nitridation of or oxidation of the silicon-containing film to form a silicon oxynitride film.

In various embodiments, the apparatus includes instructions to cause any of the above described embodiments to be performed in the apparatus.

These and other aspects are described further below with reference to the drawings.

### BRIEF DESCRIPTION OF THE DRAWINGS

FIG. 1A is a process flow diagram depicting operations that may be performed in accordance with certain disclosed embodiments.

FIG. 1B is a process flow diagram depicting operations that may be performed in accordance with certain disclosed embodiments.

FIG. 1C is a process flow diagram depicting operations that may be performed in accordance with certain disclosed embodiments.

FIG. 1D shows example schematic illustrations of layers deposited and oxidized in accordance with certain disclosed embodiments.

FIG. 2 is a timing diagram showing operations that may be performed in accordance with certain disclosed embodiments.

FIG. 3 is a schematic diagram of an example process chamber for performing certain disclosed embodiments.

FIG. 4 is a schematic diagram of an example process tool for performing certain disclosed embodiments.

FIG. 5 is a schematic diagram of an example process tool for performing certain disclosed embodiments.

FIG. 6 is a chart showing growth rate per cycle of silicon nitride.

FIGS. 7A, 7B, and 7C are FTIR of silicon nitride films.

FIG. 8 shows graphs of impurity concentrations of silicon nitride films.

FIG. 9 shows growth per cycle of silicon nitride films as a function of pedestal temperature.

FIG. 10 shows film thickness uniformity for silicon nitride films.

FIGS. 11A and 11B depict graphs of growth per cycle and refractive index for films deposited in accordance with certain disclosed embodiments.

FIGS. 12A and 12B depict graphs of growth per cycle and refractive index for films deposited in accordance with certain disclosed embodiments.

FIGS. 13A and 13B depict graphs of growth per cycle and refractive index for films deposited in accordance with certain disclosed embodiments.

FIG. 14 is a Fourier transform infrared spectroscopy (FTIR) spectra of silicon oxynitride materials deposited using certain disclosed embodiments.

FIG. 15 is a graph showing sidewall thickness and in-feature depth for a silicon oxynitride film deposited using certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processing may involve depositing silicon nitride (“SiN”) materials. While SiN may be deposited using thermal atomic layer deposition (ALD) in a furnace, furnace deposition has limitations in its ability to tune and control film properties of the deposited SiN. Alternatively, plasma-based processes that use remote plasma may be used but controllability of the film properties may also be limited, and in some cases, damage to a layer under which the SiN deposited may still be present.

Semiconductor fabrication processes may involve utilization of halogen-containing precursors. For example, deposition of silicon nitride may involve using halogen-containing precursors such as dichlorosilane (DCS) and/or hexachlorodisilane (HCDS), as well as ammonia during conversion. However, process chambers that are used to process semiconductor wafers using these chemistries may include metal components, such as aluminum-containing pedestals, aluminum-containing focus rings, and aluminum-containing showerheads and lift pins. Although aluminum is provided here as an example, it is understood that other metals may be used for the metal components. For example, some components may be made of nickel.

When halogen-containing precursors contact metal surfaces, a metal halide may be formed, and metal halides may cause metal contamination during semiconductor substrate processing within the chamber. For example, metal halides may be formed at temperatures greater than about 450° C. In one particular example, when a dichlorosilane precursor is used to form an undercoat film on metal components, when the undercoat is exposed to ammonia during semiconductor wafer processing, corrosive hydrochloric acid (HCl) may form. As a result, halogen-containing precursors may not be used to deposit undercoat films on the metal-containing chamber components to protect the components during processing. While ceramic materials may be used for chamber components such that halogen-containing precursors may be used to form undercoat films, it may be advantageous to utilize a process chamber having one or more surfaces that are made of metal.

Semiconductor fabrication processes involve deposition of various materials, including but not limited to silicon-containing materials. Example silicon-containing materials that may be deposited during semiconductor fabrication include silicon oxide (SiOₓ), silicon nitride (SiN), silicon carbide (SiC), silicon oxynitride (SiON), silicon oxycarbide (SiOC), and silicon carbonitride (SiCN). In some fabrication applications, it may be desirable to form graded materials. A material is graded when the concentration of one or more atoms within the material varies within a portion of the material. For example, a layer of material is graded when the concentration of one or more atoms of the material is different in one region of the layer compared to another region of the material. In some cases, a graded layer is used where the layer has a gradually varying composition with more or less oxygen or nitrogen in a portion of the layer as compared to another portion of the layer. In some cases, a material is graded such that the concentration of the atom is less at or near an exposed surface of the material as compared to the concentration of the atom at a position at a particular depth of the material thickness. For example, a blanket layer of material deposited horizontally on a semiconductor substrate may be graded where the concentration of an atom at the top exposed surface is less than or greater than the concentration of the atom at the bottom of the layer that is in contact with the semiconductor substrate. In an SiON material, the relative amount of nitrogen concentration and oxygen concentration affects the refractive index, so a graded SiON material may also have varying and controllable refractive index. For example, a nitrogen-rich SiON (N-rich SiON) region may have higher refractive index than an oxygen-rich SiON (O-rich SiON) region of the same SiON layer. Nitrogen-rich SiON may have an oxygen to nitrogen atomic ratio of less than about 50%. Oxygen-rich SiON may have an oxygen to nitrogen atomic ratio of greater than about 50%. In a non-graded SiON material, the refractive index is fixed and may be about 1.45 to about 2.15; tunability of the refractive index is limited to tuning the refractive index of the entire material, as opposed to certain regions or layers within the material.

One method of depositing graded SiON is by using a furnace to deposit a SiN material, then incorporating oxygen by either controlling furnace oxidation or steam annealing to form a graded SiON film. However, furnace processing has challenges, such as involving using high temperature processing which may not be compatible with some materials already deposited on a semiconductor substrate and may challenge thermal cost, long processing time, and limited tunability.

Provided herein are methods of depositing SiN using a hybrid ALD technique. Certain disclosed embodiments involve performing one or more deposition cycles where each deposition cycle includes a silicon-containing precursor dose, a nitrogen-containing gas or plasma exposure, and a plasma exposure. In some embodiments, the deposition cycle includes a silicon-containing precursor dose, thermal conversion using a nitrogen-containing gas, and a nitrogen-containing plasma exposure that includes N* radicals, H* radicals, NH₂* radicals, NH* radicals, and other derivatives. The nitrogen-containing plasma species may include mostly NH* radicals as compared to H* radicals where a ratio of NH* to H* is greater than about 10. Certain disclosed embodiments allow tuning of process conditions to affect the properties of the deposited SiN film. Example process conditions that may be tuned include but are not limited to relative flow rate of one or more process gases, plasma conditions during plasma exposure including gas flows, radio frequency (RF) power, chamber pressure, exposure time, and more.

Certain disclosed embodiments are capable of depositing highly conformal films. Conformality of films may be measured by the step coverage. Step coverage may be calculated by comparing the average thickness of a deposited film on a bottom, sidewall, or top of a trench to the average thickness of a deposited film on a bottom, sidewall, or top of a feature or trench. A “feature” of a substrate may be a via or contact hole, which may be characterized by one or more of narrow and/or re-entrant openings, constrictions within the feature, and a high aspect ratio. High aspect ratio may refer to features having an aspect ratio of at least about 10:1 or at least about 15:1 or at least about 20:1 or at least about 50:1 or at least about 100:1 or at least about 150:1 or at least about 200:1. The terms “trench” and “feature” may be used interchangeably in the present disclosure and will be understood to include any hole, via, or recessed region of a substrate.

One example of step coverage may be calculated by dividing the average thickness of the deposited film on the sidewall by the average thickness of the deposited film at the top of the feature and multiplying it by 100 to obtain a percentage. Although ALD can deposit highly conformal films, deposition of films into high aspect ratio features becomes challenging. The step coverage and uniformity of film property along the sidewall depends on, among many factors, the transport of the deposition precursor, reactant ions and/or radicals (such as those generated by igniting a reactant gas with a plasma), and by-products. As the dimension of the trench is reduced, the transport becomes increasing difficult in the trench leading to formation of a seam and/or voids in high aspect ratio trenches.

Certain disclosed embodiments deposit SiN having a conformality of at least about 80% or at least about 90% or at least about 99% or about 100% in high aspect ratio features.

Certain disclosed embodiments are capable of depositing films having superior film properties. For example, SiN deposited using certain disclosed embodiments may exhibit lower roughness (such as less than about 25% compared to thermal SiN films), reduction of impurities (such as less than about 50% oxygen atoms), within wafer non-uniformity reduction, stress tuning (such as changing the stress from tensile to compressive), density improvement, and reduced wet etch rate in 100:1 dilute hydrofluoric acid.

Techniques described herein involve thermal atomic layer deposition (ALD). That is, in various embodiments, the reaction between an aminosilane or halosilane and an nitrogen-containing reactant to form silicon nitride is performed without igniting a plasma. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form the partial layer of film. As another example, a silicon nitride deposition cycle may include the following operations: (i) delivery/adsorption of a silicon-containing precursor, (ii) purging of the silicon-containing precursor from the chamber, (iii) delivery of a nitrogen-containing gas, and (iv) purging of the nitrogen-containing gas from the chamber.

Unlike a chemical vapor deposition (CVD) technique, ALD processes use surface mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of the silicon-containing precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second reactant, such as a nitrogen-containing reactant, is introduced to the chamber so that some of these molecules react with the silicon-containing precursor adsorbed on the surface. In some processes, the second reactant reacts immediately with the adsorbed silicon-containing precursor. The chamber may then be evacuated again to remove unbound nitrogen-containing reactant molecules. As described above, in some embodiments the chamber may not be completely evacuated. Additional ALD cycles may be used to build film thickness.

In certain embodiments, an ALD first precursor dose partially saturates the substrate surface. In some embodiments, the dose phase of an ALD cycle concludes before the precursor contacts the substrate to evenly saturate the surface. Typically, the precursor flow is turned off or diverted at this point, and only purge gas flows. By operating in this sub saturation regime, the ALD process reduces the cycle time and increases throughput. However, because precursor adsorption is not saturation limited, the adsorbed precursor concentration may vary slightly across the substrate surface. Examples of ALD processes operating in the sub-saturation regime are provided in U.S. patent application Ser. No. 14/061,587 (now U.S. Pat. No. 9,355,839), filed Oct. 23, 2013, titled “SUB-SATURATED ATOMIC LAYER DEPOSITION AND CONFORMAL FILM DEPOSITION,” which is incorporated herein by reference in its entirety.

In some implementations, ALD methods may include plasma activation. However, in thermal ALD processes described herein, plasma is not ignited. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

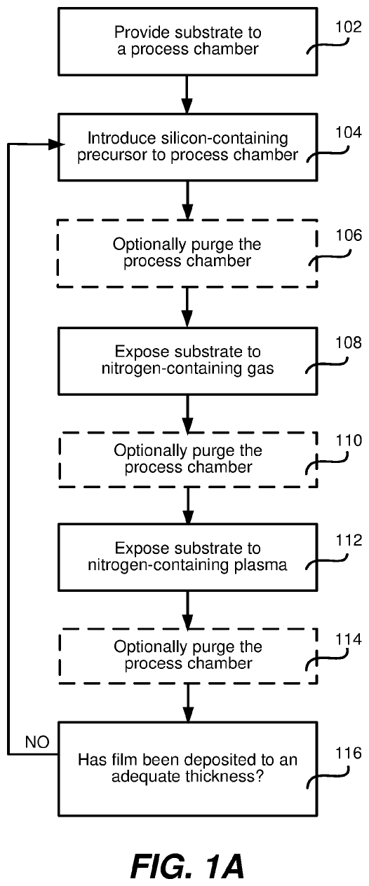

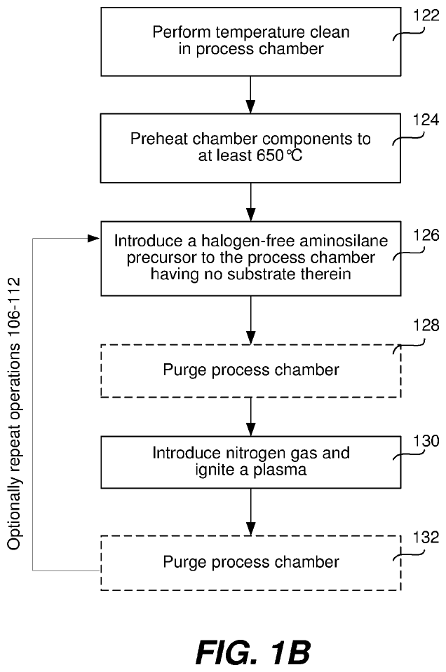

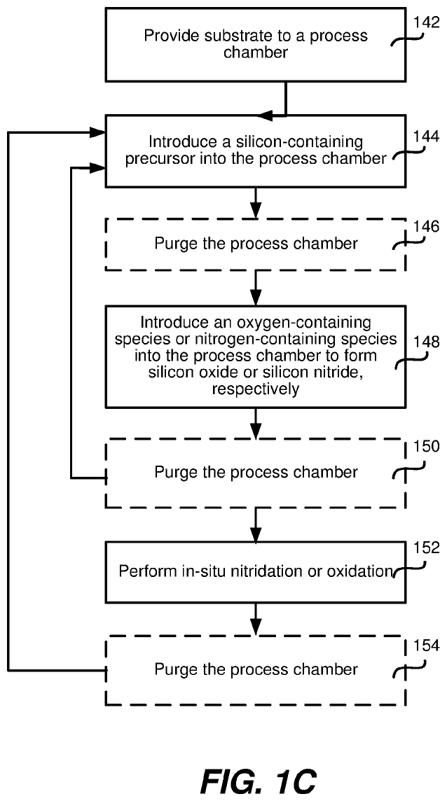

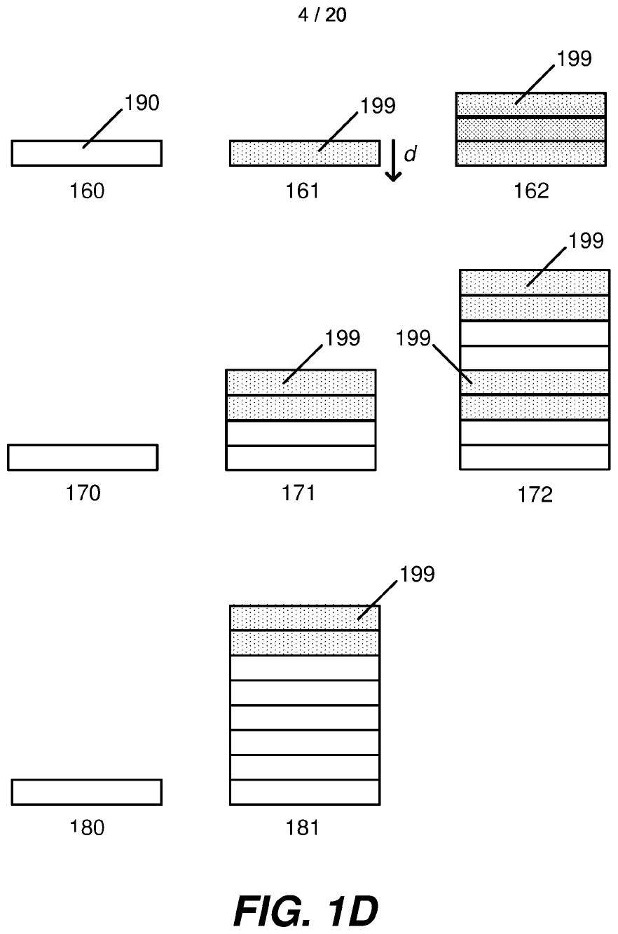

FIG. 1A provides a process flow diagram depicting operations that may be performed in accordance with certain disclosed embodiments.

In operation 102, a substrate is provided to a process chamber. In various embodiments, the process chamber is a single-wafer chamber. In some embodiments, the process chamber is a station within a multi-station chamber. Process conditions described herein are suitable for a single-wafer chamber.

The process chamber may be set to a chamber pressure about 5 mTorr to about 25 Torr or about 0.5 Torr to about 25 Torr. Such chamber pressures may be used throughout operations 104-116 as described herein. In some embodiments, chamber pressure may be different during different operations. The chamber pressure may also depend on the chemistries selected for various operations described herein.

The substrate may be heated to a substrate temperature about 25° C. to about 800° C., or about 500° C. to about 700° C., or at least about 650° C. during operations 104-108. It will be understood that substrate temperature as used herein refers to the temperature that the pedestal holding the substrate is set at and that in some embodiments, the substrate when provided to the process chamber on the pedestal may be heated to the desired substrate temperature prior to processing the substrate. The substrate temperature may be the same throughout operations 102-108 as described herein.

The substrate may be any suitable substrate. The substrate may be a silicon wafer, e.g., a 200-mm wafer, a 300-mm wafer, including wafers having one or more layers of material, such as dielectric, conducting, or semi-conducting material deposited thereon. Non-limiting examples of under layers include dielectric layers and conducting layers, e.g., silicon oxides, silicon nitrides, silicon carbides, metal oxides, metal nitrides, metal carbides, and metal layers. In some embodiments, the substrate includes silicon oxide and silicon. In some embodiments, the substrate includes a partially fabricated 3D-NAND structure.

In some embodiments, the feature(s) may have an aspect ratio of at least about 1:1, at least about 2:1, at least about 4:1, at least about 6:1, at least about 10:1, or at least about 20:1, or at least about 50:1, or at least about 100:1, or at least about 150:1, or at least about 200:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature. One or more features may have a high aspect ratio, which is defined as having an aspect ratio of greater than about 100:1 or greater than about 150:1 or greater than about 180:1.

In some embodiments, the substrate may be partially fabricated for forming a memory device. In some embodiments, exposed regions of the substrate include silicon-containing surfaces, including but not limited to low-k dielectric material, silicon oxide, silicon nitride, silicon oxynitride, silicon oxycarbide, silicon carbonitride, and silicon carbide. In some embodiments, exposed regions of the substrate include silicon oxynitride.

In operation 104, a silicon-containing precursor may be introduced to the process chamber. In various embodiments, the silicon-containing precursor is a silane. Non-limiting examples of silanes that may be used include but are not limited to substituted and unsubstituted silanes, halosilanes, aminosilanes, organosilanes, alkylsilanes, alkylaminosilanes, and alkylhalosilanes. Additional examples of silicon-containing precursors are included elsewhere herein such as in the Definitions and Precursors section. In some embodiments, the silicon-containing precursor is a halosilane such as one or more of the following: dichlorosilane (DCS), hexachlorodisilane (HCDS), tetrachlorosilane, or other chlorosilane precursors.

In some embodiments, the silicon-containing precursor may be flowed at a flow rate of about 100 sccm to about 2000 sccm for a single-wafer chamber. The silicon-containing precursor may be flowed with an inert push gas, such as nitrogen gas or argon gas or a mixture of nitrogen and argon gas. The flow rate of the inert push gas may be about 300 sccm to about 1500 sccm for a single-wafer chamber. Operation 104 may be performed for a duration of about 0.1 second to about 100 seconds. During operation 104, the process chamber may have a chamber pressure of about 5 Torr to about 25 Torr. In some embodiments, additional nitrogen gas may be introduced with the silicon-containing precursor and/or the inert push gas for dilution, for pressure stability, or both. The additional nitrogen gas may be flowed at a flow rate of about 500 sccm to about 2000 sccm for a single-wafer chamber. In one example, dichlorosilane is introduced to a chamber housing the substrate at a flow rate of about 1000 sccm for about 5 seconds at a chamber pressure of about 9.5 Torr in a plasma-free environment.

In operation 106, the process chamber is optionally purged. Operation 106 involves stopping flow of the silicon-containing precursor and introducing flow of an inert gas or a purge gas to remove excess silicon-containing precursor molecules that are not adsorbed onto a surface of the substrate or silicon-containing precursor molecules in a processing region of the process chamber over the substrate in gas phase.

Example inert or purge gases include but are not limited to nitrogen gas and argon. Flow rate of the inert or purge gas during operation 106 is about 1000 sccm to about 40000 sccm for a single-wafer chamber. Introduction of the inert or purge gas may be performed for a duration of about 0.1 second to about 10 seconds. During operation 106, the chamber pressure may be about 0.5 Torr to about 22 Torr. In some embodiments, a lower pressure may be used to purge more effectively. For example, in some embodiments, a pressure of less than about 0.1 Torr or about 0.1 Torr may be used. In some embodiments, the chamber pressure during operation 106 is the same as the chamber pressure used during operation 104. In one example, nitrogen gas is introduced at a flow rate of about 10000 sccm for about 10 seconds at a chamber pressure of about 9.5 Torr. The flow rate, duration, and chamber pressure may depend on the precursor used in operation 106. Operation 106 is performed without igniting a plasma. Operation 106 is performed 35 in a plasma-free environment.

In operation 108, the substrate is exposed to a nitrogen-containing gas for thermal conversion. The nitrogen-containing gas may be introduced without igniting a plasma. The nitrogen-containing gas may be introduced in a plasma-free environment. The nitrogen-containing gas is introduced at a flow rate of about 2000 sccm to about 10000 sccm for a single-wafer chamber.

A nitrogen-containing reactant is a reactant or mixture of reactants that includes at least one nitrogen. Non-limiting examples include nitrogen (N₂), ammonia, hydrazine, amines (amines bearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary, or quaternary (for example, tetraalkylammonium compounds). A nitrogen-containing reactant can contain heteroatoms other than nitrogen, for example, hydroxylamine, t-butyloxycarbonyl amine, and N-t-butyl hydroxylamine are nitrogen-containing reactants. Example nitrogen-containing reactants include nitrogen gas, ammonia, and amines. An example hydrazine is N₂H₄. An example amine is tributylamine. The nitrogen-containing gas may also be hydrogen-containing. The nitrogen-containing gas may be ammonia (NH₃) gas in various embodiments.

In some embodiments, a hydrogen-containing gas may also be flowed during operation 108. In some embodiments, the hydrogen-containing gas is hydrogen (H₂) gas. Hydrogen may be flowed at a flow rate of about 0 sccm to about 5000 sccm for a single-wafer chamber.

In some embodiments, NH₃ is introduced with one or more of a dilution gas, such as nitrogen, or argon, or both. In some embodiments, during exposure to the nitrogen-containing gas without igniting a plasma, nitrogen is flowed at a flow rate of about 500 sccm to about 2000 sccm for a single-wafer chamber as a dilution gas. Argon may be flowed at a flow rate of about 10 slm to about 40 slm for a single-wafer chamber.

Exposure to the nitrogen-containing gas without igniting a plasma may be performed for a duration of about 1 second to about 120 seconds. Exposure to the nitrogen-containing gas without igniting a plasma may be performed at a chamber pressure of about 5 Torr to about 25 Torr.

In some embodiments, a higher pressure may be used in operation 108 to improve conformality of the film being deposited. For example, in some embodiments, a pressure of at least about 20 Torr or at least about 22 Torr, or at least about 30 Torr, or about 20 Torr to about 30 Torr may be used.

In one example, NH₃ is introduced at a flow rate of about 4500 sccm for 60 seconds at a chamber pressure of 9.5 Torr. During this operation, the silicon-containing precursor is at least partially converted to silicon nitride such that the nitrogen-containing gas thermally converts adsorbed silicon-containing precursor to silicon nitride.

In operation 110, the chamber is optionally purged. Purging may be performed using any one or more of the process gases and conditions described above with respect to operation 106. In one example, nitrogen gas is flowed at a flow rate of about 10000 sccm for about 10 seconds in a chamber having a chamber pressure of about 9.5 Torr.

In some embodiments, operations 106-110 may be performed for multiple cycles prior to performing operation 112.

In operation 112, the substrate is exposed to nitrogen-containing plasma. Operation 112 may involve flowing or introducing nitrogen-containing plasma to the substrate. The nitrogen-containing plasma may be generated by igniting one or more nitrogen-containing gases, including but not limited to ammonia gas and nitrogen gas. Nitrogen gas may be flowed at a flow rate of about 5000 sccm or about 25000 sccm or about 10000 sccm to about 25000 sccm or about 12000 sccm for a single-wafer chamber. Ammonia gas may be flowed at a flow rate of about 0 sccm to about 500 sccm or about 50 sccm to about 250 sccm or about 125 sccm. In some embodiments, the nitrogen-containing gas is an ammonia-free gas. In some embodiments, the nitrogen-containing gas does not include ammonia. In some embodiments, ammonia is 0 sccm. In some embodiments, hydrogen gas is also flowed during operation 112. Hydrogen gas may be flowed at a flow rate of about 0 sccm to about 100 sccm. Operation 112 may be performed for a duration of about 1 second to about 30 seconds. Operation 112 may be performed in a chamber having a chamber pressure of about 1 Torr to about 10 Torr. Operation 112 may be performed at a chamber pressure that less than about 40% of the chamber pressure used in operation 108 or 104. In some embodiments, a chamber pressure of about 3 Torr to about 6 Torr may be used to tune conformality of the film being deposited. In some embodiments, a lower pressure may be used to tune film properties.

The plasma generated in this operation may have a plasma power of about 500 W to about 6000 W. In various embodiments, the plasma may be an inductively coupled plasma or a capacitively coupled plasma. An inductively coupled plasma may be set at a plasma between about 500 W to about 6000 W. In some embodiments, a bias may be applied between about 0V and about 1000V.

In one example, nitrogen gas is flowed at a flow rate of about 12000 sccm, with ammonia gas flowed at about 125 sccm, and plasma is generated from this mixture of gases and exposed to the substrate for about 10 seconds in a chamber having a pressure of about 6 Torr.

In various embodiments, a remote plasma may be used. The plasma introduced to the process chamber may be primarily radical based. In some embodiments, the substrate is exposed to N* only radicals or a mixture of N*, and NH* radicals. In some embodiments, the ratio of H* to NH* radicals may be about 0.1:1 to about 0:1.

Different gas mixtures in the plasma may generate different mixtures of radicals. For example, in some embodiments, plasma generated from a nitrogen-only gas may contain N* radicals, or mostly N* radicals, or only N* radicals. In some embodiments, plasma generated from a nitrogen-containing gas mixture having nitrogen gas, ammonia gas, and/or hydrogen gas may include N* radicals as well as H* radicals and NH* radicals. In some embodiments, an abundance of N* is present in the chamber and the relative concentration of N* is a few order of magnitudes higher than that of NH*.

In operation 114, the process chamber is optionally purged. Purging may be performed using any one or more of the process gases and conditions described above with respect to operation 106 or operation 110. In one example, nitrogen gas is flowed at a flow rate of about 10000 sccm for about 10 seconds in a chamber having a chamber pressure of about 9.5 Torr.

In operation 116, it is determined whether the film is deposited to an adequate thickness. If not, operations 104, 108, and 112 may be optionally repeated, or operations 104-114 may be optionally repeated, in cycles.

Certain disclosed embodiments are capable of depositing silicon nitride films into features whereby growth rate on sidewalls of the feature improves by about 1.7 times or about 2 times or more as compared to performing thermal conversion only (such as only exposing to cycles of silicon-containing precursor and a nitrogen-containing gas without a plasma, and without additionally adding an operation of exposing to a nitrogen-containing plasma after or during the cycles). For example, the growth rate may be about 0.75 Å per cycle (where one cycle includes a silicon-containing precursor dose, thermal conversion using ammonia gas, and exposure to RF plasma generated from ammonia and nitrogen gas) as compared to thermal conversion, which may have a growth rate of about 0.44 Å per cycle (where one cycle includes a silicon-containing precursor dose and thermal conversion using ammonia gas).

Additionally, incorporating both thermal conversion and an exposure to nitrogen-containing plasma operation results in increased step coverage, as compared to a plasma-only process (for example, cycles of a silicon-containing precursor dose and exposure to nitrogen-containing plasma without also performing thermal conversion may result in a step coverage of about 75%).

Provided herein are also methods for depositing and apparatuses having undercoat films on metal-containing chamber components using a halogen-free deposition precursor. Methods involve using an aminosilane precursor and nitrogen plasma to form undercoat films on metal-containing components of chambers. These undercoat films can then protect the chamber components during semiconductor wafer processing, such as when components are exposed to halogen-containing precursors for depositing silicon nitride. Undercoat films are deposited using a halogen-free process. Undercoat films are deposited using an ammonia-free process. In various embodiments, undercoat films are deposited using a halogen-free and ammonia-free process. Certain disclosed embodiments also allow deposition of undercoat films on components that may be set at different temperatures. For example, a pedestal may be set at a temperature of about 650° C. while a showerhead and chamber walls may be set to a temperature of 100° C. Chambers having undercoat films deposited using certain disclosed embodiments can be used to process substrates that have little to no metal contamination. Certain disclosed embodiments may also have the advantage of increasing the life of one or more chamber components.

Certain disclosed embodiments may be used for any process chamber having metal-containing components, or for any process chamber that is used for semiconductor wafer processing that involves using a halogen-containing precursor, or an ammonia-containing reactant.

FIG. 1B provides a process flow diagram having operations that may be performed in accordance with certain disclosed embodiments. In operation 122, a temperature clean operation is performed. In some embodiments, the temperature clean operation is referred to as a “pre-clean” operation. During operation 122, the process chamber does not contain any substrate. In some embodiments, the process chamber in operation 122 is subject to a temperature clean operation because it was previously utilized for semiconductor wafer processing and may have materials deposited on components therein from the processing operations that are cleaned before processing the next semiconductor wafer or wafers. For example, if the process chamber has residual silicon nitride material on its surfaces, a temperature clean may be performed at a temperature of about 350° C. to about 550° C., or about 400° C., using nitrogen trifluoride. In some embodiments, on a pedestal having aluminum, some aluminum fluoride may be formed.

In operation 124, one or more chamber components may be heated to a temperature of at least about 650° C. In various embodiments, operation 124 is performed to perform controlled heating of one or more chamber components to prevent evaporation of metal halides, such as aluminum fluoride, which may have been generated from operation 122. Evaporation of such metal halides may cause deposition at or near the showerhead, and cause metal contamination at or near the top of a wafer when a wafer is later processed in the process chamber. Operation 124 may be performed using a flow rate from a showerhead of at least about 10 slm to divert metal halides such as aluminum fluoride to a pump. The flow rate may be about 10 slm to about 40 slm. The gas flowed from the showerhead may be any one or more inert gases, including but not limited to nitrogen gas. During operation 124, the chamber pressure may be set at a pressure of at least about 0.5 Torr and about 4 Torr to about 8 Torr. Without being bound by a particular theory, it is believed that flow dynamics with pressure affect the effectiveness of certain disclosed embodiments and pressure of at least about 0.5 Torr is used to allow sufficient cleaning of the chamber using certain disclosed embodiments. During operation 124, a substrate is still not present in the process chamber.

In operation 126, a halogen-free aminosilane precursor is introduced to the process chamber. In operation 126, the process chamber still contains no substrate, or is substrate-free. The aminosilane precursor is introduced to provide a precursor for forming the undercoat film. In some embodiments, the aminosilane precursor is diisopropylaminosilane (DIPAS). Additional examples of precursors are described elsewhere herein in the Precursors section.

In operation 126 of FIG. 1B, the undercoat film may be deposited using atomic layer deposition (ALD). The undercoat may be deposited by plasma-enhanced atomic layer deposition (PEALD). That is, in various embodiments, the reaction between an aminosilane and a nitrogen-containing reactant to form a silicon nitride undercoat is performed using a plasma. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form the partial layer of film. As another example, a silicon nitride deposition cycle may include the following operations: (i) delivery/adsorption of an aminosilane precursor, (ii) purging of the aminosilane precursor from the chamber, (iii) delivery of plasma species generated from a nitrogen-containing gas, and (iv) purging of the plasma species from the chamber.

Unlike a chemical vapor deposition (CVD) technique, ALD processes use surface mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when the compound is adsorbed onto the substrate surface as described herein, the adsorbed layer may include the compound as well as derivatives of the compound. For example, an adsorbed layer of an aminosilane precursor may include the aminosilane precursor as well as derivatives of the aminosilane precursor. After a first precursor dose, the chamber is then evacuated to remove most or all of the aminosilane precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second reactant, such as a nitrogen-containing reactant, is introduced to the chamber so that some of these molecules react with the aminosilane precursor adsorbed on the surface when a plasma is generated. In some processes, the second reactant reacts immediately with the adsorbed aminosilane precursor. The chamber may then be evacuated again to remove unbound second reactant molecules. As described above, in some embodiments the chamber may not be completely evacuated. Additional ALD cycles may be used to build film thickness.

In certain embodiments, an ALD first precursor dose partially saturates the substrate surface. In some embodiments, the dose phase of an ALD cycle concludes before the precursor contacts the substrate to evenly saturate the surface. Typically, the precursor flow is turned off or diverted at this point, and only purge gas flows. By operating in this sub saturation regime, the ALD process reduces the cycle time and increases throughput. However, because precursor adsorption is not saturation limited, the adsorbed precursor concentration may vary slightly across the substrate surface. Examples of ALD processes operating in the sub-saturation regime are provided in U.S. patent application Ser. No. 14/061,587 (now U.S. Pat. No. 9,355,839), filed Oct. 23, 2013, titled “SUB-SATURATED ATOMIC LAYER DEPOSITION AND CONFORMAL FILM DEPOSITION,” which is incorporated herein by reference in its entirety.

In some implementations, ALD methods may include plasma activation. However, in thermal ALD processes described herein, plasma is not ignited. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

During operation 126, the aminosilane precursor may be flowed at a flow rate of about 100 sccm to about 2000 sccm for a single-wafer chamber. In some embodiments, the aminosilane precursor may be flowed with a push gas, such as nitrogen gas, using a flow rate of about 300 sccm to about 1500 sccm for a single-wafer chamber. A push gas is flown to the ampoule and both the precursor and push gas are flowed into the chamber. Using a push gas may allow delivery of more precursor to the chamber. In some embodiments, the push gas can also dilute precursor flow. In some embodiments, the aminosilane precursor is diluted with a dilution gas. A dilution gas may be used to dilute the precursor such that the precursor is uniformly distributed to all parts of a chamber during cleaning. The dilution gas may be flowed using a flow rate of about 500 sccm to about 2000 sccm. The flow rate ratio of dilution gas to aminosilane precursor may be about 0.1:1 to about 10:1.

During operation 126, the chamber pressure may be set at a pressure of about 1 Torr to about 25 Torr. Operation 126 may be performed for a duration of about 0.1 second to about 10 seconds.

Returning to FIG. 1B, in operation 128, the chamber is optionally purged. Purging the chamber may involve flowing a purge gas or a sweep gas, which may be a carrier gas used in other operations or may be a different gas. In some embodiments, purging may involve evacuating the chamber. Examples of purge gases include argon (Ar), nitrogen (N₂), hydrogen (H₂), helium (He), oxygen (O₂), krypton (Kr), xenon (Xe), neon (Ne), and combinations thereof. In various embodiments, the purge gas is an inert gas. The purge gas may include one or more gases. In some embodiments, operation 128 may include one or more evacuation subphases for evacuating the process chamber. Alternatively, it will be appreciated that operation 128 may be omitted in some embodiments. In some embodiments, increasing a flow rate of one or more purge gases may decrease the duration of operation 128. For example, a purge gas flow rate may be adjusted according to various reactant thermodynamic characteristics and/or geometric characteristics of the process chamber and/or process chamber plumbing for modifying the duration of operation 128. In one non-limiting example, the duration of a purge phase may be adjusted by modulating purge gas flow rate. This may reduce deposition cycle time, which may improve substrate throughput. After a purge, the aminosilane molecules remain adsorbed onto the substrate surface.

The flow rate of the purge gas may about 1000 sccm to about 40000 sccm for a single-wafer chamber. The duration of operation 128 may be about 0.1 seconds to about 10 seconds. The chamber pressure during operation 128 may be about 0.5 Torr to about 25 Torr.

In operation 130, a nitrogen-containing gas is introduced and a plasma is generated to convert adsorbed aminosilane precursor molecules to silicon nitride. In various embodiments, the nitrogen-containing gas is nitrogen gas. The flow rate of the nitrogen-containing gas may be about 5000 sccm to about 25000 sccm for a single-wafer chamber. The duration of operation 130 may be about 0.1 second to about 30 seconds. The chamber may be set to a pressure of about 1 Torr to about 10 Torr.

Plasma is used during this operation to generate a plasma or reactive species containing nitrogen. Plasma may be generated using a single frequency or a dual frequency plasma. For a dual frequency plasma, high frequency plasma is generated at a plasma power of about 100 W to about 6000 W for a single-wafer chamber and low frequency plasma is generated at a plasma power of about OW to about 2500 W for a single-wafer chamber. Inductively coupled plasma, microwave plasma, and capacitively coupled plasmas may be used. Relative to operation 126, the ratio of flow rate of nitrogen gas to aminosilane precursor gas may be about 1:100 to about 1:5. In some embodiments, operation 130 is performed using an ion filter in the showerhead such that only or most of the plasma species that enter the process chamber are nitrogen radicals.

In operation 132, the chamber is optionally purged. Purging may be performed using any of the chemistries, methods, and process conditions described above with respect to operation 128. In some embodiments, the chamber is purged using nitrogen as a purge gas. Nitrogen may be flowed at a flow rate of about 1000 sccm to about 40000 sccm for a single-wafer chamber. Operation 130 may be performed for a duration of about 0.1 second to about 10 seconds. The chamber pressure may be about 0.5 Torr to about 25 Torr.

Operations 126, 128, 130, and 132 may constitute an atomic layer deposition cycle. In each cycle, the amount of thickness of silicon nitride film formed may be about 0.5 Å to about 2 Å. In various embodiments, about 100 to about 5000 cycles or about 1000 cycles may be performed until a desired thickness of a silicon nitride undercoat is formed. In various embodiments, the undercoat is deposited to a thickness of at least about 300 Å. The growth rate per cycle on some components, such as components that are set to a temperature of about 100° C. may be about 0.18±0.04 Å/cycle. The growth rate per cycle on some components, such as components that are set to a temperature of about 650° C. may be about 0.35±0.06 Å/cycle.

Although not shown, after a sufficient thickness of undercoat film is formed, a substrate may be provided to the process chamber for processing, including processing that may involve introducing a halogen-containing gas or species.

In some embodiments, operations 126-132 are performed at a constant chamber pressure. In various embodiments, operations 126-132 are performed using a process that is halogen-free. In various embodiments, operations 126-132 are performed using a process that is ammonia-free. In various embodiments, operations 126-132 are performed using a process that is both halogen-free and ammonia-free. Because halogens are not present during the forming of the undercoat film, metal halides are not formed and metal contamination is reduced and/or eliminated in wafers that are subsequently processed in the process chamber.

Provided herein are also methods and apparatuses for forming SiON using a single-wafer non-furnace deposition tool. Certain disclosed embodiments are capable of forming SiON that is conformal. Certain disclosed embodiments are also able to form graded SiON films, which may be conformal as well. Disclosed embodiments can be implemented for forming SiON in a wide variety of applications, including but not limited to forming SiON in high aspect ratio features, and forming graded SiON in very thin SiON layers, and forming a tunneling layer in 3D-NAND memory applications. Certain disclosed embodiments allow a wide tuneability range for controlling the gradient of oxidation and refractive index. Deposition and oxidation control can both be performed in-situ or within the same chamber or within the same tool. Certain disclosed embodiments involve forming a first silicon-containing film, such as silicon nitride or silicon oxide, by ALD, followed by in-situ oxidation or in-situ nitridation to convert the first silicon-containing film into a second silicon-containing film such as SiON. For example, in-situ oxidation can convert silicon nitride to SiON. In-situ nitridation can convert silicon oxide to SiON. The amount of in-situ oxidation or nitridation can be used to modulate the amount of oxygen and/or nitrogen in the deposited film.

Techniques described herein involve thermal atomic layer deposition (ALD). That is, in various embodiments, the reaction between a silicon-containing precursor and a reactant to form a silicon oxide or silicon nitride film that can then be modulated to form SiON. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form the partial layer of film. As another example, a silicon oxide deposition cycle may include the following operations: (i) delivery/adsorption of a silane precursor, (ii) purging of the silane precursor from the chamber, (iii) delivery of an oxygen-containing gas, and (iv) purging of the oxygen-containing gas from the chamber.

Unlike a chemical vapor deposition (CVD) technique, ALD processes use surface mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of the silicon-containing precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second reactant, such as an oxygen-containing reactant or nitrogen-containing reactant, is introduced to the chamber so that some of these molecules react with the silicon-containing precursor adsorbed on the surface. In some processes, the second reactant reacts immediately with the adsorbed silicon-containing precursor. The chamber may then be evacuated again to remove unbound second reactant molecules. As described above, in some embodiments the chamber may not be completely evacuated. Additional ALD cycles may be used to build film thickness.

In certain embodiments, an ALD first precursor dose partially saturates the substrate surface. In some embodiments, the dose phase of an ALD cycle concludes before the precursor contacts the substrate to evenly saturate the surface. Typically, the precursor flow is turned off or diverted at this point, and only purge gas flows. By operating in this sub saturation regime, the ALD process reduces the cycle time and increases throughput. However, because precursor adsorption is not saturation limited, the adsorbed precursor concentration may vary slightly across the substrate surface. Examples of ALD processes operating in the sub-saturation regime are provided in U.S. patent application Ser. No. 14/061,587 (now U.S. Pat. No. 9,355,839), filed Oct. 23, 2013, titled “SUB-SATURATED ATOMIC LAYER DEPOSITION AND CONFORMAL FILM DEPOSITION,” which is incorporated herein by reference in its entirety.

In some implementations, ALD methods may include plasma activation. In some implementations, ALD methods may not include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

FIG. 1C shows a process flow diagram depicting operations that may be performed in accordance with certain disclosed embodiments. It will be understood that the selection of gases in operations 148 and 152 determine the type of material and level of gradation or relative concentrations of oxygen and nitrogen, as well as process conditions used for various operations described herein.

In operation 142, a substrate is provided to a process chamber. In various embodiments, the process chamber is a single-wafer chamber. In some embodiments, the process chamber is a station within a multi-station chamber. Process conditions described herein are suitable for a single-wafer chamber.

The process chamber may be set to a chamber pressure about 5 mTorr to about 25 Torr or about 10 Torr to about 25 Torr. Such chamber pressures may be used throughout operations 142-154 as described herein. In some embodiments, chamber pressure may be different during different operations. The chamber pressure may also depend on the chemistries selected for various operations described herein.

The substrate may be heated to a substrate temperature about 25° C. to about 800° C., or about 500° C. to about 700° C., or at least about 650° C. during operations 144-154. It will be understood that substrate temperature as used herein refers to the temperature that the pedestal holding the substrate is set at and that in some embodiments, the substrate when provided to the process chamber on the pedestal may be heated to the desired substrate temperature prior to processing the substrate. The substrate temperature may be the same throughout operations 142-154 as described herein.

The substrate may be any suitable substrate. The substrate may be a silicon wafer, e.g., a 200-mm wafer, a 300-mm wafer, including wafers having one or more layers of material, such as dielectric, conducting, or semi-conducting material deposited thereon. Non-limiting examples of under layers include dielectric layers and conducting layers, e.g., silicon oxides, silicon nitrides, silicon carbides, metal oxides, metal nitrides, metal carbides, and metal layers. In some embodiments, the substrate includes silicon oxide and silicon. In some embodiments, the substrate includes a partially fabricated 3D-NAND structure.

In some embodiments, the feature(s) may have an aspect ratio of at least about 1:1, at least about 2:1, at least about 4:1, at least about 6:1, at least about 10:1, or at least about 20:1, or at least about 50:1, or at least about 100:1, or at least about 150:1, or at least about 200:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature.

One or more features may have a high aspect ratio, which is defined as having an aspect ratio of greater than about 100:1 or greater than about 150:1 or greater than about 180:1.

In some embodiments, the substrate may be partially fabricated for forming a memory device. In some embodiments, exposed regions of the substrate include silicon-containing surfaces, including but not limited to silicon and SiON.

In an operation 144, a silicon-containing precursor is introduced to the process chamber. In various embodiments, the silicon-containing precursor is a silane. Non-limiting examples of silanes that may be used include but are not limited to substituted and unsubstituted silanes, halosilanes, aminosilanes, organosilanes, alkylsilanes, alkylaminosilanes, and alkylhalosilanes. In particular embodiments, the silicon-containing precursor includes a halosilane precursor. In particular embodiments, the silicon-containing precursor includes an aminosilane precursor. Additional examples of silicon-containing precursors are included elsewhere herein such as in the Definitions and Precursors section.

Flow rate of the silicon-containing precursor in operation 144 may range from about 100 sccm to about 5000 sccm for a 4-station chamber, or about 100 sccm to about 4000 sccm for a 4-station chamber, or about 100 sccm to about 2000 sccm for a single-wafer chamber. Exposure in operation 144 may range from about 0.1 seconds to about 10 seconds. Chamber pressure during operation 144 may be about 5 Torr to about 25 Torr. In some embodiments, the silicon-containing precursor is flowed with a dilution gas. The dilution gas may be flowed at a flow rate of about 500 sccm to about 2000 sccm for a single-wafer chamber. In some embodiments, the dilution gas is an inert gas. In some embodiments, the dilution gas is nitrogen gas (N₂). In some embodiments, the dilution gas is co-flowed with the silicon-containing precursor. In some embodiments, the dilution gas is co-flowed with the silicon-containing precursor and then diverted prior to delivery to the process chamber. In some embodiments, the silicon-containing precursor is flowed with the dilution gas into the process chamber.

In various embodiments, a plasma is not ignited in operation 144. In some embodiments, operation 144 is plasma-free. In some embodiments, the silicon-containing gas is introduced to the process chamber in a plasma-free environment.

In various embodiments, introduction of the silicon-containing gas to the process chamber forms at least a partial adsorbed layer of the silicon-containing gas to exposed surfaces of the substrate. In some embodiments, introduction of the silicon-containing gas to the process chamber is referred to as a “dose.” In some embodiments, introduction of the silicon-containing gas to the process chamber is a “dose” of an ALD cycle.

In one example, during a dose, dichlorosilane or hexachlorodisilane or silicon tetrachloride is introduced to a single-wafer process chamber at a flow rate of about 100 sccm to about 2000 sccm or about 1000 sccm for about 0.1 second to about 10 seconds or about 5 seconds at a chamber pressure of about 5 Torr to about 25 Torr or about 9.5 Torr using nitrogen as a dilution gas having a flow rate of about 500 sccm to about 2000 sccm.

In one example, during a dose, an aminosilane such as DIPAS or BTBAS is introduced to the single-wafer process chamber at a flow rate of about 100 sccm to about 2000 sccm or about 900 sccm for about 0.1 second to about 10 seconds or about 2 seconds at a chamber pressure of about 5 Torr to about 25 Torr or about 18 Torr using nitrogen as a dilution gas having a flow rate of about 500 sccm to about 2000 sccm.

In operation 146, the process chamber is optionally purged. Purging the chamber may involve flowing a purge gas or a sweep gas, which may be a carrier gas used in other operations or may be a different gas. In some embodiments, purging may involve evacuating the chamber. Example purge gases include argon, nitrogen, hydrogen, and helium. In some embodiments, operation 146 may include one or more evacuation subphases for evacuating the process chamber. Alternatively, it will be appreciated that operation 146 may be omitted in some embodiments. Operation 146 may have any suitable duration, such as between about 0 seconds and about 60 seconds, or about 0.1 second to about 10 seconds. In some embodiments, increasing a flow rate of one or more purge gases may decrease the duration of operation 146. For example, a purge gas flow rate may be adjusted according to various reactant thermodynamic characteristics and/or geometric characteristics of the process chamber and/or process chamber plumbing for modifying the duration of operation 146. In one non-limiting example, the duration of a purge phase may be adjusted by modulating purge gas flow rate. This may reduce deposition cycle time, which may improve substrate throughput. After a purge, the silicon-containing precursor remains adsorbed onto the surface of the substrate.

The flow rate of one or more purge gases may be about 1000 sccm to about 40000 sccm. The chamber pressure during purging may be about 0.5 Torr to about 22 Torr. A lower pressure may be used to purge more effectively.

In one example, during operation 146, nitrogen gas is flowed at a flow rate of about 10000 sccm for 10 seconds at a chamber pressure of about 9.5 Torr.

In operation 148, a reactant species is introduced to convert or react with the silicon-containing precursor to form a first silicon-containing film. For example, an oxygen-containing species may be used to form a silicon oxide film. A nitrogen-containing species may be used to form a silicon nitride film. The reactant species may be a gas or a plasma or may be both. In some embodiments, an oxygen-containing gas or nitrogen-containing gas is introduced to the process chamber to form silicon oxide or silicon nitride, respectively. For example, an oxygen-containing gas may be introduced to react with adsorbed silicon-containing precursor on a surface of the substrate to convert the adsorbed silicon-containing precursor to silicon oxide. In another example, a nitrogen-containing gas may be introduced to react with adsorbed silicon-containing precursor on a surface of the substrate to convert the adsorbed silicon-containing precursor to silicon nitride.

In some embodiments, operation 148 is performed as part of a thermal process. In some embodiments, operation 148 is performed as part of a plasma-free deposition process. In some embodiments, operation 148 also includes igniting a plasma. The plasma may be ignited in-situ, such as within the chamber, so that as oxygen-containing gas or nitrogen-containing gas is flowed into the chamber, and the gas is ignited to form an oxygen-containing plasma or nitrogen-containing plasma, respectively. The plasma may be ignited remotely, such that an oxygen-containing plasma species or nitrogen-containing plasma species is introduced to the process chamber instead of or with an oxygen-containing gas or nitrogen-containing gas. Where operation 148 involves forming silicon oxide, operation 152 may involve nitridation. Where operation 148 involves forming silicon nitride, operation 152 may involve oxidation. In some embodiments, one or more operations of introducing an oxygen-containing gas or nitrogen-containing gas may be used to modulate or control the relative amounts of oxygen and nitrogen in the deposited film.

The following description is related to embodiments where conversion in operation 148 is used to form an oxide.

If oxygen-containing gas or oxygen-containing plasma species (generated from an oxygen-containing gas) are introduced in operation 148, one or more of the following process conditions may be used. The oxygen-containing gas may be any suitable oxygen-containing gas, such as but not limited to oxygen (O₂), carbon dioxide, carbon monoxide, hydrogen peroxide, other peroxides, and ozone. The oxygen-containing gas may be mixed with or diluted with one or more inert gases. In some embodiments, the oxygen-containing gas is mixed with or diluted with hydrogen gas. In some embodiments, the oxygen-containing gas is mixed with hydrogen gas and diluted with nitrogen gas. The flow rate of oxygen-containing gas may be about 100 sccm to about 5000 sccm for a single-wafer chamber. The flow rate of hydrogen or inert gas may be about 0 sccm to about 5000 sccm. The flow rate of a dilution gas or nitrogen gas may be about 500 sccm to about 2000 sccm. Operation 148 may be performed for a duration of about 1 second to about 30 seconds, or about 5 seconds to about 15 seconds. After a few cycles of deposition, such as about 25 cycles of deposition, a longer conversion time of about 300 seconds to about 900 seconds, or about 300 seconds, or about 900 seconds may be used. In a mixture of oxygen and hydrogen gas, the ratio of oxygen to hydrogen may be about 1:10 to about 10:1. In some embodiments, hydrogen is not used. In some embodiments, the flow rate of hydrogen gas is 0 sccm.

In some embodiments, hydrogen is ignited to form a hydrogen plasma. In some embodiments, an oxygen and hydrogen-containing plasma may be used in operation 148. In some embodiments, and in some cycles of deposition, operation 148 may be oxygen-free. In some embodiments and in some cycles of deposition, operation 148 may involve only introducing a hydrogen plasma. In some embodiments, operation 148 uses a hydrogen plasma and is oxygen-free. A hydrogen plasma may be used to reduce the chlorine content or fluorine content in the deposited film.

Process conditions used in operation 148 may be used to tune film properties, such as change the stress of the deposited film. In some embodiments, this operation may also involve subsequently exposing to a nitrogen plasma. In some embodiments, an inert plasma may be used to anneal the film after conversion to improve film quality. In one example, annealing is performed using a plasma. For example, about 5000 sccm to about 20000 sccm (for a 4-station chamber) of nitrogen gas may be ignited using RF power of about 2000 W to about 6000 W for a duration of about 0.1 second to about 30 seconds. The plasma may be generated in situ. In some embodiments, the plasma may be generated remotely.

The plasma conditions used for operation 148 varies depending on the chemistries used. In one example, the plasma may be ignited using a plasma power of about 2000 W to about 6000 W having a 13.6 MHz frequency. In one example, an oxygen- and hydrogen-containing plasma is generated in situ using a flow rate of about 4500 sccm of a mixture of oxygen and hydrogen gas, and the substrate is exposed to the oxygen- and hydrogen-containing plasma for a duration of about 15 seconds at a chamber pressure of about 18 Torr.

The following description is related to embodiments where conversion in operation 148 is used to form an nitride.

If nitrogen-containing gas or nitrogen-containing plasma species (generated from an nitrogen-containing gas) are introduced in operation 148, one or more of the following process conditions may be used. The nitrogen-containing gas may be any suitable nitrogen-containing gas, such as but not limited to nitrogen (N₂), nitrous oxide, nitric oxide, deuterated ammonia (ND₃), and ammonia. The nitrogen-containing gas may be mixed with or diluted with one or more inert gases. In some embodiments, the nitrogen-containing gas is mixed with or diluted with hydrogen gas. The flow rate of nitrogen-containing gas may be about 2000 sccm to about 40000 sccm for a single-wafer chamber. The flow rate of hydrogen or inert gas may be about 0 sccm to about 5000 sccm. The flow rate of a dilution gas or additional nitrogen gas may be about 500 sccm to about 2000 sccm. Operation 148 may be performed for a duration of about 1 second to about 30 seconds. In a mixture of ammonia and hydrogen gas, the amount of hydrogen in the mixture is about 0% to about 90% of the flow.

In some embodiments, a nitrogen-containing plasma is used. Plasma may be generated by flowing about 5000 sccm to about 40000 sccm of nitrogen gas, about 50 sccm to about 250 sccm of ammonia, and about 0 sccm to about 100 sccm of hydrogen gas for about 1 second to about 30 seconds in a chamber having a pressure of about 1 Torr to about 10 Torr.

In some embodiments, a thermal conversion may be performed followed by plasma conversion. For example, operation 148 may involve first flowing a nitrogen-containing gas without a plasma then flowing a nitrogen-containing gas and igniting a plasma. In some embodiments, where thermal conversion is performed followed by plasma conversion, an optional purging operation may be performed after thermal conversion and before plasma conversion. Purging may be performed using any of the techniques, gases, and process conditions described above with respect to operation 146.

For plasma conversion, the plasma conditions used for operation 148 varies depending on the chemistries used. In one example, the plasma may be ignited using a plasma power of about 1000 W to about 6000 W having a 13.6 MHz frequency. In one example, about 4500 sccm of ammonia is introduced for about 15 seconds at a chamber pressure of about 9.5 Torr to convert a silicon-containing precursor to silicon nitride.

Referring to FIG. 1C, in operation 150, the process chamber may again be optionally purged. Purging may be performed using any of the techniques, gases, and process conditions described above with respect to operation 146.

Operations 144-150 may be optionally repeated in cycles. Operations 144-150 may constitute one ALD cycle. In some embodiments, about 1 to about 1000 or about 1 to about 100 cycles of ALD are performed.

In operation 152, an in-situ nitridation or oxidation operation is performed to convert the first silicon-containing film into a second silicon-containing film, which may be a converted film by nitriding or oxidizing the film deposited from operations 144 and 148. In one example of in-situ oxidation, a mixture of hydrogen gas, oxygen gas, and inert gas (such as nitrogen gas and/or argon gas) may be used. A higher partial pressure of P_{O}_{₂} and P_{H}_{₂} may cause oxidation to occur faster. In some embodiments, a higher partial pressure of P_{O}_{₂} and P_{H}_{₂} may be caused by lowering inert gas flow and increasing pressure. In a specific, non-limiting example, in an experiment implementing oxidation at a pressure of 22 Torr with hydrogen flow of about 4500 sccm and oxygen flow of about 4500 sccm with inert gas flow of about 4200 sccm, when inert gas flow is increased, oxidation effectiveness decreased. When pressure was decreased, oxidation effectiveness decreased.

Operation 152 may be performed in-situ. In some embodiments, operation 152 is performed in the same chamber as performing any one or more of operations 144 and 148. The selection of nitridation versus oxidation depends on whether the film already deposited is to be tailored to include more nitrogen atoms or more oxygen atoms. For example, in some embodiments, operations 144 and 148 may be performed to form a silicon nitride layer. To oxidize the silicon nitride to form SiON, in-situ oxidation may be performed. In another example, in some embodiments, operations 144 and 148 may be performed to form a silicon oxide layer. To nitridize the silicon oxide to form SiON, in-situ nitridation may be performed. In some embodiments, after oxidation or nitridation or other cycles of ALD, nitridation and/or oxidation may further be performed to tailor the composition of the deposited film. In some embodiments, operation 152 is performed so as to form a graded layer, with either graded oxygen content, graded nitrogen content, or both. In some embodiments, the graded layer includes graded oxygen content and graded nitrogen content whereby regions with increased amount of oxygen also have increased amount of nitrogen, or regions with decreased amount of oxygen also have decreased amounts of nitrogen.

In-situ oxidation may be performed by introducing a oxygen-containing reactant such as a oxygen-containing gas or plasma species. A oxygen-containing plasma species may be generated by igniting a oxygen-containing gas. An example oxygen-containing reactant is oxygen gas. Another example oxygen-containing reactant is carbon dioxide. In some embodiments, any one or more of the chemistries used and/or process conditions used as described above for exposing to a oxygen-containing gas or plasma to form silicon oxide in operation 148 may be performed in operation 152 as an in-situ oxidation operation. For example, in some embodiments, if oxygen-containing gas or oxygen-containing plasma species (generated from an oxygen-containing gas) are introduced in operation 152, one or more of the following process conditions may be used. The oxygen-containing gas may be any suitable oxygen-containing gas, such as but not limited to oxygen (O2), carbon dioxide, carbon monoxide, hydrogen peroxide, other peroxides, and ozone. The oxygen-containing gas may be mixed with or diluted with one or more inert gases. In some embodiments, the oxygen-containing gas is mixed with or diluted with hydrogen gas. In some embodiments, the oxygen-containing gas is mixed with hydrogen gas and diluted with nitrogen gas. The flow rate of oxygen-containing gas may be about 100 sccm to about 5000 sccm for a single-wafer chamber. The flow rate of hydrogen or inert gas may be about 0 sccm to about 5000 sccm. The flow rate of a dilution gas or nitrogen gas may be about 500 sccm to about 2000 sccm. Operation 152 may be performed for a duration of about 1 second to about 900 seconds. In a mixture of oxygen and hydrogen gas, the ratio of oxygen to hydrogen may be about 1:2 to about 1:1.

In some embodiments, hydrogen is ignited to form a hydrogen plasma. In some embodiments, an oxygen and hydrogen-containing plasma may be used in operation 148. In some embodiments, and in some cycles of deposition, operation 148 may be oxygen-free. In some embodiments and in some cycles of deposition, operation 148 may involve only introducing a hydrogen plasma. In some embodiments, operation 148 uses a hydrogen plasma and is oxygen-free. A hydrogen plasma may be used to reduce the chlorine content or fluorine content in the deposited film.

Process conditions used in operation 152 may be used to tune film properties, such as change the stress of the deposited film. In some embodiments, this operation may also involve subsequently exposing to a nitrogen plasma. In some embodiments, an inert plasma may be used to anneal the film after conversion to improve film quality.

The plasma conditions used for operation 152 varies depending on the chemistries used. In one example, the plasma may be ignited using a plasma power of about 1000 W to about 6000 W having a 13.56 MHz frequency. In one example, an oxygen- and hydrogen-containing plasma is generated in situ using a flow rate of about 4500 sccm of a mixture of oxygen and hydrogen gas, and the substrate is exposed to the oxygen- and hydrogen-containing plasma for a duration of about 15 seconds at a chamber pressure of about 18 Torr.

In-situ nitridation may be performed by introducing a nitrogen-containing reactant such as a nitrogen-containing gas or plasma species. A nitrogen-containing plasma species may be generated by igniting a nitrogen-containing gas. An example nitrogen-containing reactant is ammonia. Another example nitrogen-containing reactant is nitrogen gas. In some embodiments, any one or more of the chemistries used and/or process conditions used as described above for exposing to a nitrogen-containing gas or plasma to form silicon nitride in operation 148 may be performed in operation 152 as an in-situ nitridation operation. For example, in some embodiments, if nitrogen-containing gas or nitrogen-containing plasma species (generated from an nitrogen-containing gas) are introduced in operation 148, one or more of the following process conditions may be used. The nitrogen-containing gas may be any suitable nitrogen-containing gas, such as but not limited to nitrogen (N₂), and ammonia. The nitrogen-containing gas may be mixed with or diluted with one or more inert gases. In some embodiments, the nitrogen-containing gas is mixed with or diluted with hydrogen gas. The flow rate of nitrogen-containing gas may be about 2000 sccm to about 40000 sccm for a single-wafer chamber. The flow rate of hydrogen or inert gas may be about 0 sccm to about 5000 sccm. The flow rate of a dilution gas or additional nitrogen gas may be about 500 sccm to about 2000 sccm. Operation 148 may be performed for a duration of about 1 second to about 30 seconds. In a mixture of ammonia and hydrogen gas, the amount of hydrogen in the mixture may be about 0% to about 90% by flow or by partial pressure.

In some embodiments, a nitrogen-containing plasma is used. Plasma may be generated by flowing about 5000 sccm to about 10000 sccm of nitrogen gas, about 50 sccm to about 250 sccm of ammonia, and about 0 sccm to about 100 sccm of hydrogen gas for about 1 second to about 30 seconds in a chamber having a pressure of about 1 Torr to about 10 Torr.

In some embodiments, a thermal conversion may be performed followed by plasma conversion. For example, operation 148 may involve first flowing a nitrogen-containing gas without a plasma then flowing a nitrogen-containing gas and igniting a plasma. In some embodiments, where thermal conversion is performed followed by plasma conversion, an optional purging operation may be performed after thermal conversion and before plasma conversion. Purging may be performed using any of the techniques, gases, and process conditions described above with respect to operation 146.

The plasma conditions used for operation 152 varies depending on the chemistries used. In one example, the plasma may be ignited using a plasma power of about 1000 W to about 6000 W having a 13.56 MHz frequency. In one example, about 4500 sccm of ammonia is introduced for about 15 seconds at a chamber pressure of about 9.5 Torr to convert a silicon-containing precursor to silicon nitride.

Operation 152 tunes the nitrogen and/or oxygen content, as well as refractive index, and other properties of the film. In some embodiments, operation 152 helps convert the deposited film to a SiON film. In some embodiments, after operation 152, a graded film is formed, such as a graded SiON film.

In operation 154, the process chamber may be optionally purged. Purging may be performed using any of the chemistries and/or process conditions described above with respect to operation 146. In some embodiments, if the desired thickness of film is not yet achieved, operations 144, 148, and 152 may be repeated in cycles. Performing each of operation 144, 148, and 152 once may constitute one cycle. The total number of cycles may be used to control thickness of the film.

In some embodiments, performing operation 144, operation 148 where an oxygen-containing gas or plasma is used, and operation 152 where in-situ nitridation is performed involves forming a graded film where a region of the film closer to the exposed surface of the deposited film may have a higher refractive index and/or be nitrogen-rich and another region of the film of the film may have a lower refractive index and/or be oxygen-rich. The in-situ nitridation time and pressure can be used to modulate the amount of gradient and the refractive index of the film in different regions of the film. In contrast, in non-graded films, more cycles of ALD (e.g., operations 144 and 148) may result in a higher refractive index and decreasing in-situ nitridation time and pressure can be used to lower refractive index. A non-graded film may have a refractive index of about 1.45 to about 2.15.

In some embodiments, performing operation 144, operation 148 where an nitrogen-containing gas or plasma is used, and operation 152 where in-situ oxidation is performed involves forming a graded film where a region of the film closer to the exposed surface of the deposited film may have a higher refractive index and/or be nitrogen-rich and another region of the film of the film may have a lower refractive index and/or be oxygen-rich. The in-situ oxidation time and pressure can be used to modulate the amount of gradient and the refractive index of the film in different regions of the film. In contrast, in non-graded films, more cycles of ALD (e.g., operations 144 and 148) may result in a higher refractive index and decreasing in-situ oxidation time and pressure can be used to lower refractive index. A non-graded film may have a refractive index of about 1.45 to about 2.15.

Nitridation or oxidation may be performed to a particular depth of the thickness of the film deposited by one or more cycles of operations 144 and 148. FIG. 1D shows three non-limiting examples for forming SiON by depositing silicon nitride by ALD and using in-situ oxidation. While this example involves ALD cycles for forming silicon nitride and in-situ oxidation, it will be understood that such examples may also be used for forming silicon oxide and in-situ nitridation, and other embodiments described herein.

In the first example including diagrams 160, 161, and 162, each bar 190 is representative of one ALD cycle for depositing silicon nitride. In 160, one ALD cycle is performed. In 161, oxidation is performed such that it oxidizes to a penetration depth d to form an oxidized silicon nitride material 199. Cycles of deposition and oxidation are performed to form a fully oxidized film 162 having oxidized silicon nitride material 199.

In the second example including diagrams 170, 171, and 172, each bar is also representative of one ALD cycle for depositing silicon nitride. In 170, one ALD cycle is performed. In 171, the example shows that after 4 cycles of ALD, oxidation is performed. Oxidation is performed only up to a certain penetration depth; here, it shows that it penetrates to two of the layers deposited by ALD to form oxidized silicon nitride material 199. In 172, multiple cycles of deposition and oxidation is performed such that for every 4 cycles of ALD, oxidation is performed that penetrates two layers of the deposited film; this forms nanolaminates within the material, which can be used to control refractive index.

In the third example including diagrams 180 and 181, each bar is also representative of one ALD cycle for depositing silicon nitride. In 180, one ALD cycle is performed. In 181, after multiple ALD cycles are performed, oxidation is performed. Oxidation is performed only up to a certain penetration depth; here, it shows that despite 8 ALD cycles being performed, only the last two layers of material deposited by ALD cycles are penetrated with oxidation. This can be performed to form a graded SiON material; here, the top region has higher oxygen concentration than the bottom region. The oxidation time and process conditions can be used to modulate the oxygen and nitrogen content of the film.

The level of gradation for a graded film may vary. In some regions of the deposited material, a SiON film may have about 0.1% atomic to about 67% atomic oxygen or about 57% atomic to about 0.1% atomic nitrogen.

Films deposited by certain disclosed embodiments may be conformal. Films deposited by ALD are typically conformal. Conformality of films may be measured by the step coverage. Step coverage may be calculated by comparing the average thickness of a deposited film on a bottom, sidewall, or top of a trench to the average thickness of a deposited film on a bottom, sidewall, or top of a feature or trench. A “feature” of a substrate may be a via or contact hole, which may be characterized by one or more of narrow and/or re entrant openings, constrictions within the feature, and a high aspect ratio. The terms “trench” and “feature” may be used interchangeably in the present disclosure and will be understood to include any hole, via, or recessed region of a substrate.

One example of step coverage may be calculated by dividing the average thickness of the deposited film on the sidewall by the average thickness of the deposited film at the top of the feature and multiplying it by 100 to obtain a percentage. Although ALD can deposit highly conformal films, deposition of films into high aspect ratio features becomes challenging. The step coverage and uniformity of film property along the sidewall depends on, among many factors, the transport of the deposition precursor, reactant ions and/or radicals (such as those generated by igniting a reactant gas with a plasma), and by-products. As the dimension of the trench is reduced, the transport becomes increasing difficult in the trench leading to formation of a seam and/or voids in high aspect ratio trenches.

The step coverage for films deposited using certain disclosed embodiments may be at least about 90% or about 98% to about 102%.

Certain disclosed embodiments may also be suitable for a wide variety of applications, including but not limited to forming SiON tunneling layers in a 3D-NAND structure. Certain disclosed embodiments may also be suitable for forming SiON films in high aspect ratio features, such as features having aspect ratios of at least 100:1 or higher.

Certain disclosed embodiments may also be used in conjunction with dep-etch-dep processes. For example, filling certain features, such as high aspect ratio features or reentrant features or features having sloped sidewalls or sidewalls with topography, it may be advantageous to partially deposit a film, then preferentially etch the film at or near the feature opening, and then deposit more film into the feature. When integrated with certain disclosed embodiments, etching may be performed after operation 148 and before operation 152, or may be performed after operation 152 between cycles of performing operations 144, 148, and 152, or in other variations. In one example, etching may be performed every 5 cycles of operations 144 and operation 148, for several cycles, followed by performing operation 152. The time at which to perform the etching may be determined by when the feature opening is or expects to be closed or almost closed. Etching may be performed using a variety of chemistries, such as but not limited to fluorine-containing etchants such as nitrogen trifluoride.

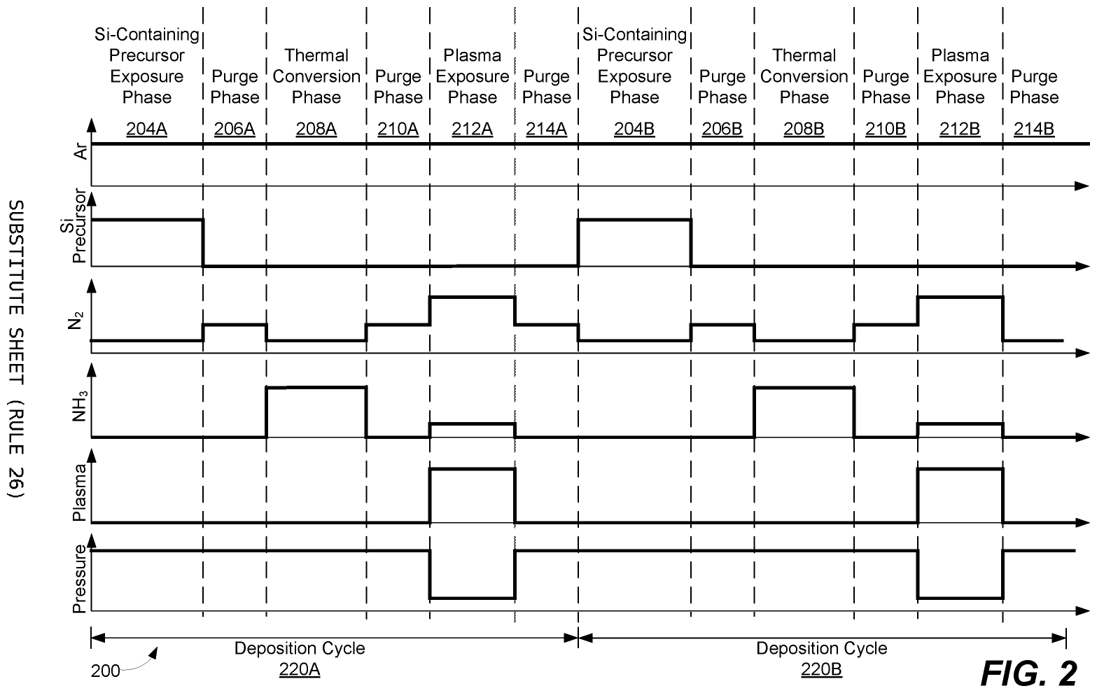

FIG. 2 shows an example timing schematic diagram in accordance with a method such as described above with respect to FIG. 1A that shows various phases that may be used in accordance with one example of a method of performing certain disclosed embodiments. While certain phases and certain relative amounts are shown in FIG. 2, it will be understood that other variations may be performed in accordance with certain disclosed embodiments. FIG. 2 shows six process conditions but it will be understood that fewer or more process conditions may be toggled during each phase in accordance with certain disclosed embodiments and that while specific gases are listed (Ar, N2, and NH3), other suitable gases as described herein may be used.

Example 200 includes two deposition cycles-deposition cycle 220A and deposition cycle 220B. It will be understood that more or less than two deposition cycles may be performed, and that multiple sub-cycles may be performed within one deposition cycle. For example, phases 204A, 206A, 208A, and 210A may constitute a sub-cycle, which may be repeated in multiple cycles within one deposition cycle 220A or 220B. However, repetitions of sub-cycles are not depicted in this particular example in FIG. 2.

Deposition cycle 220A includes silicon-containing precursor exposure phase 204A, purge phase 206A, thermal conversion phase 208A, purge phase 210A, plasma exposure phase 212A, and purge phase 214A. Silicon-containing precursor exposure phase 204A may correspond to operation 104 of FIG. 1A. During silicon-containing precursor exposure phase 204A, argon flow is on and constant, and may be used as an inert gas, dilution gas, or carrier gas; silicon-containing precursor flow is on and constant; nitrogen gas flow is on, lower as compared to other phases, and constant; ammonia gas flow is off; plasma is off; and pressure is higher as compared to some other phases. Purge phase 206A may correspond to operation 106 of FIG. 1A. In purge phase 206A, argon flow continues to flow as it may be used as a purge gas; silicon-containing precursor flow is turned off; nitrogen gas continues to flow and its flow rate may be slightly increased to a medium flow (as compared to other phases); ammonia gas flow continues to be turned off; plasma continues to be turned off; and pressure may stay constant. Thermal conversion phase 208A may correspond to operation 108 of FIG. 1A. In thermal conversion phase 208A, argon flow continues to flow as it may be used as a carrier gas or inert gas or dilution gas; silicon-containing precursor flow remains off; nitrogen gas may continue to flow and may be reduced relative to purge phase 206A; ammonia gas flow may be turned on; plasma remains off; and pressure may remain constant. Purge phase 210A may correspond to operation 110 of FIG. 1A. During purge phase 210A, argon flow continues to flow as it may be used as a purge gas; silicon-containing precursor flow remains off; nitrogen gas continues to flow and its flow rate may be slightly increased to a medium flow (as compared to thermal conversion phase 208A); ammonia gas flow is turned off; plasma continues to be turned off; and pressure may stay constant. Plasma exposure phase 212A may correspond to operation 112 of FIG. 1A. During plasma exposure phase 212A, argon flow continues to flow as it may be used as a carrier gas or inert gas or dilution gas; silicon-containing precursor flow remains off; nitrogen gas flow may be increased which may be used to facilitate generation of nitrogen-containing plasma such as N* radicals; ammonia gas flow may be turned on but may have a lower flow rate relative to thermal conversion phase 208A; plasma is turned on; and chamber pressure is lowered relative to other phases. Purge phase 214A may correspond to operation 114 of FIG. 1A. During purge phase 214A, argon flow continues to flow as it may be used as a purge gas; silicon-containing precursor flow remains off; nitrogen gas continues to flow and its flow rate may be slightly reduced relative to the plasma exposure phase 212A; ammonia gas flow is turned off; plasma is turned off; and pressure is increased to a pressure that may be the same as during phases other than the plasma exposure phase 212A.

It may be determined that the film thickness of deposited silicon nitride is insufficiently thick and the cycle may be repeated in accordance with operation 116 of FIG. 1A such as shown in the example in deposition cycle 220B of FIG. 2, which includes silicon-containing precursor exposure phase 204B, purge phase 206B, thermal conversion phase 208B, purge phase 210B, plasma exposure phase 212B, and purge phase 214B.

Silicon-containing precursor exposure phase 204B may correspond to a repeated operation 104 of FIG. 1A. During silicon-containing precursor exposure phase 204B, argon flow is on and constant, and may be used as an inert gas, dilution gas, or carrier gas; silicon-containing precursor flow is on and constant; nitrogen gas flow is on, lower as compared to other phases, and constant; ammonia gas flow is off; plasma is off; and pressure is higher as compared to some other phases. Purge phase 206B may correspond to a repeated operation 106 of FIG. 1A. In purge phase 206B, argon flow continues to flow as it may be used as a purge gas; silicon-containing precursor flow is turned off; nitrogen gas continues to flow and its flow rate may be slightly increased to a medium flow (as compared to other phases); ammonia gas flow continues to be turned off; plasma continues to be turned off; and pressure may stay constant. Thermal conversion phase 208B may correspond to a repeated operation 108 of FIG. 1A. In thermal conversion phase 208B, argon flow continues to flow as it may be used as a carrier gas or inert gas or dilution gas; silicon-containing precursor flow remains off; nitrogen gas may continue to flow and may be reduced relative to purge phase 206B; ammonia gas flow may be turned on; plasma remains off; and pressure may remain constant. Purge phase 210B may correspond to a repeated operation 110 of FIG. 1A. During purge phase 210B, argon flow continues to flow as it may be used as a purge gas; silicon-containing precursor flow remains off; nitrogen gas continues to flow and its flow rate may be slightly increased to a medium flow (as compared to thermal conversion phase 208B); ammonia gas flow is turned off; plasma continues to be turned off; and pressure may stay constant. Plasma exposure phase 212B may correspond to a repeated operation 112 of FIG. 1A. During plasma exposure phase 212B, argon flow continues to flow as it may be used as a carrier gas or inert gas or dilution gas; silicon-containing precursor flow remains off; nitrogen gas flow may be increased which may be used to facilitate generation of nitrogen-containing plasma such as N* radicals; ammonia gas flow may be turned on but may have a lower flow rate relative to thermal conversion phase 208B; plasma is turned on; and chamber pressure is lowered relative to other phases. Purge phase 214B may correspond to a repeated operation 114 of FIG. 1A. During purge phase 214B, argon flow continues to flow as it may be used as a purge gas; silicon-containing precursor flow remains off; nitrogen gas continues to flow and its flow rate may be slightly reduced relative to the plasma exposure phase 212B; ammonia gas flow is turned off; plasma is turned off; and pressure is increased to a pressure that may be the same as during phases other than the plasma exposure phase 212B.

In some embodiments, certain disclosed embodiments may be combined. For example, an undercoat may be used in a chamber in accordance with FIG. 1B may be formed prior to or after operations in FIG. 1A or in FIG. 1C. Additionally, in some embodiments, operations in FIGS. 1A and 1C can also be combined. For example, in-situ nitridation or oxidation in operation 152 may be performed in combination with exposing the substrate to the nitrogen-containing plasma in operation 112.

### Apparatus

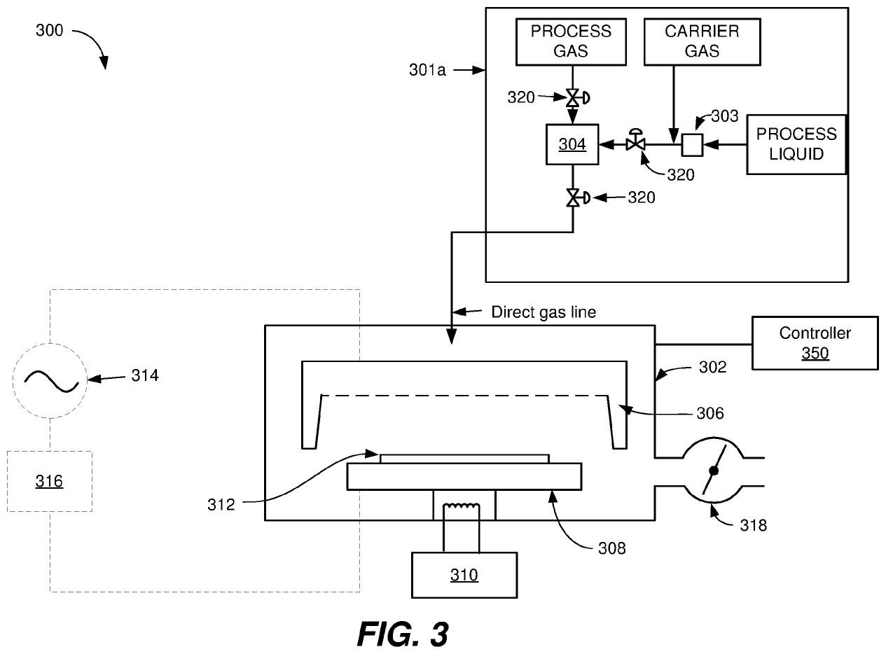

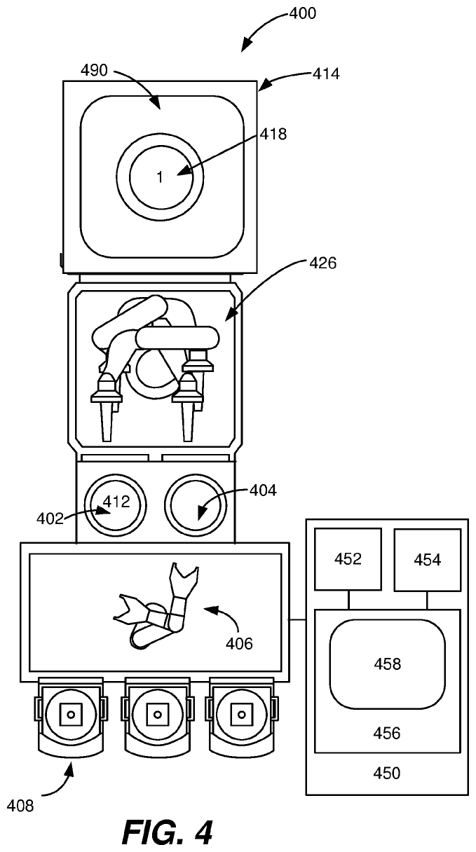

FIG. 3 depicts a schematic illustration of an embodiment of an atomic layer deposition (ALD) process station 300 having a process chamber body 302. In various embodiments, a single process station 300 is implemented in a tool such as shown in FIG. 4. In some embodiments, a plurality of ALD process stations 300 may be included in a low pressure process tool environment. For example, FIG. 3 depicts an embodiment of a multi-station processing tool 300. In some embodiments, one or more hardware parameters of ALD process station 300 including those discussed in detail below may be adjusted programmatically by one or more computer controllers 350.

ALD process station 300 fluidly communicates with reactant delivery system 301a for delivering process gases to a showerhead 306. Reactant delivery system 301a includes a mixing vessel 304 for blending and/or conditioning process gases, such as a silicon-containing precursor gas, or nitrogen-containing gas, for delivery to showerhead 306. One or more mixing vessel inlet valves 320 may control introduction of process gases to mixing vessel 304. One or more valves 305 may control introduction of gases to the showerhead 306.

As an example, the embodiment of FIG. 3 includes a vaporization point 303 for vaporizing liquid reactant to be supplied to the mixing vessel 304. In some embodiments, vaporization point 303 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 303 may be heat traced. In some examples, mixing vessel 304 may also be heat traced. In one non-limiting example, piping downstream of vaporization point 303 has an increasing temperature profile extending from approximately 40° C. to approximately 55° C. or from about 60° C. to about 65° C. at mixing vessel.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 303. In one scenario, a liquid injector may be mounted directly to mixing vessel. In another scenario, a liquid injector may be mounted directly to showerhead 306.

In some embodiments, a liquid flow controller (LFC) upstream of vaporization point 303 may be provided for controlling a mass flow of liquid for vaporization and delivery to ALD process station 300. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 306 distributes process gases toward substrate 312. In the embodiment shown in FIG. 3, the substrate 312 is located beneath showerhead 306 and is shown resting on a pedestal 308. Showerhead 306 may have any suitable shape, and may have any suitable number and arrangement of ports for distributing process gases to substrate 312.

In some embodiments, pedestal 308 may be raised or lowered to expose substrate 312 to a volume between the substrate 312 and the showerhead 306. It will be appreciated that, in some embodiments, pedestal height may be adjusted programmatically by a suitable computer controller 350.

In another scenario, adjusting a height of pedestal 308 may allow a plasma density to be varied during plasma activation in the process in embodiments where a plasma is ignited. At the conclusion of the process phase, pedestal 308 may be lowered during another substrate transfer phase to allow removal of substrate 312 from pedestal 308.

In some embodiments, pedestal 308 may be temperature controlled via heater 310. In some embodiments, the pedestal 308 may be heated to a temperature of about 25° C. to about 800° C., or about 200° C. to about 700° C., during deposition of silicon nitride films as described in disclosed embodiments. In some embodiments, the pedestal is set at a temperature of about 45° C. to about 800° C., or about 500° C. to about 700° C. In some embodiments, the same pedestal 308 is used for multiple operations in accordance with certain disclosed embodiments.

Further, in some embodiments, pressure control for ALD process station 300 may be provided by butterfly valve 318. As shown in the embodiment of FIG. 3, butterfly valve 318 throttles a vacuum provided by a downstream vacuum pump (not shown). However, in some embodiments, pressure control of ALD process station 300 may also be adjusted by varying a flow rate of one or more gases introduced to the ALD process station 300.

In some embodiments, a position of showerhead 306 may be adjusted relative to pedestal 308 to vary a volume between the substrate 312 and the showerhead 306. Further, it will be appreciated that a vertical position of pedestal 308 and/or showerhead 306 may be varied by any suitable mechanism within the scope of the present disclosure. In some embodiments, pedestal 308 may include a rotational axis for rotating an orientation of substrate 312. It will be appreciated that, in some embodiments, one or more of these example adjustments may be performed programmatically by one or more suitable computer controllers 350.

In some embodiments where plasma may be used as discussed above, showerhead 306 and pedestal 308 electrically communicate with a radio frequency (RF) power supply 314 and matching network 316 for powering a plasma. For example, plasma may be used for igniting a nitrogen-containing plasma in hybrid ALD. In some embodiments, the plasma energy may be controlled by controlling one or more of a process station pressure, a gas concentration, an RF source power, an RF source frequency, and a plasma power pulse timing. For example, RF power supply 314 and matching network 316 may be operated at any suitable power to form a plasma having a desired composition of radical species. Examples of suitable powers are about 150 W to about 10000 W or about 500 W to about 6000 W for a single-station chamber. For a 3-station chamber, the plasma power may include three generators each powered up to about 10000 W, for a total of about 30000 W.

In some embodiments, the substrate may be exposed to nitrogen-containing gas while igniting a plasma during a plasma exposure phase. The plasma may be generated remotely (such as in a remote plasma generator) or directly in a chamber housing the substrate (i.e. in situ). RF power supply 314 may provide RF power of any suitable frequency. In some embodiments, RF power supply 314 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 3.45 GHZ, or greater than about 13.56 MHz, or greater than 27 MHz, or greater than 30 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 350 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of a silicon-containing precursor gas, instructions for setting a flow rate of a carrier gas (such as argon), and time delay instructions for the first recipe phase. A second recipe phase may include modulating or stopping a flow rate of an inert and/or a reactant gas, instructions for optionally heating, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of a nitrogen-containing gas and time delay instructions for the third recipe phase. A fourth recipe phase may include instructions for modulating or stopping a flow rate of an inert and/or a reactant gas, instructions for modulating the flow rate of a carrier or purge gas, and time delay instructions for the fourth recipe phase. A fifth, subsequent recipe phase may include instructions for setting a flow rate of a nitrogen-containing gas, instructions for igniting a plasma, and instructions for modulating a flow rate of a carrier or purge gas and time delay instructions for the fifth recipe phase. A sixth recipe phase may include instructions for modulating or stopping a flow rate of an inert and/or a reactant gas, instructions for modulating the flow rate of a carrier or purge gas, and time delay instructions for the sixth recipe phase.

In another example, a first recipe phase may include instructions for setting a flow rate of an aminosilane gas, instructions for setting a flow rate of a carrier gas (such as argon), and time delay instructions for the first recipe phase. A second recipe phase may include modulating or stopping a flow rate of an inert and/or a reactant gas, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of an oxygen-containing gas and time delay instructions for the third recipe phase. A fourth recipe phase may include instructions for modulating or stopping a flow rate of an inert and/or a reactant gas, instructions for modulating the flow rate of a carrier or purge gas, and time delay instructions for the fourth recipe phase. A fifth, subsequent recipe phase may include instructions for modulating or stopping a flow rate of an inert and/or a reactant gas, instructions for heating or igniting a plasma, and instructions for modulating a flow rate of a carrier or purge gas and time delay instructions for the fifth recipe phase.

In another example, a first recipe phase may include instructions for setting a flow rate of a silicon-containing gas, instructions for setting a flow rate of a carrier gas (such as argon), and time delay instructions for the first recipe phase. A second recipe phase may include modulating or stopping a flow rate of an inert and/or a reactant gas, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of an oxygen-containing or nitrogen-containing gas and time delay instructions for the third recipe phase. A fourth recipe phase may include instructions for modulating or stopping a flow rate of an inert and/or a reactant gas, instructions for modulating the flow rate of a carrier or purge gas, and time delay instructions for the fourth recipe phase. A fifth, subsequent recipe phase may include instructions for setting a flow rate of a nitridation or oxidation gas, instructions for optionally heating or igniting a plasma, and instructions for modulating a flow rate of a carrier or purge gas and time delay instructions for the fifth recipe phase.

It will be appreciated that these recipe phases may be further subdivided and/or iterated in any suitable way within the scope of the disclosed embodiments. In some embodiments, the controller 350 may include any of the features described below with respect to system controller 450 of FIG. 4 and system controller 350 of FIG. 3.

A process station may be included in a single-station chamber or single-chamber tool such as shown in FIG. 4. FIG. 4 depicts an example processing apparatus according to disclosed embodiments. Tool 400 includes a processing chamber 414 which includes a processing station 490 may process a wafer. The processing chamber 414 is configured to deposit silicon oxide, deposit silicon nitride, anneal substrates using thermal or plasma anneals, and the like.

Tool 400 also includes a wafer transfer unit configured to transport wafers within the tool 400. Additional features of tool 400 will be discussed in greater detail below, and various features are discussed here with respect to some of the described techniques. In the depicted illustration, the wafer transfer unit includes a first robotic arm unit 426 in a first wafer transfer module and a second robotic arm unit 406 in a second wafer transfer module that may be considered an equipment front end module (EFEM) configured to received containers for wafers, such as a front opening unified module (FOUP) 408. The first robotic arm unit 426 is configured to transport a wafer between the processing chamber 414 and the second robotic arm unit via module 404 which may hold multiple wafers such as shown in module 402 with substrate 412. The second robotic arm unit 406 is configured to transport the wafer between a FOUP and module 404, or from module 402 to FOUP. After a wafer has been prepared in the module 404, the wafer transfer unit is able to transfer the wafer to first processing chamber 414 for deposition and optional anneal in situ.

Similar to above, the first wafer transfer module may a vacuum transfer module (VTM). Airlock or module 404, also known as a loadlock, is shown and may be individually optimized to perform various fabrication processes. The tool 400 also includes a FOUP 408 that is configured to lower the pressure of the tool 400 to a vacuum or low pressure, e.g., between about 1 mTorr and about 10 Torr, and maintain the tool 400 at this pressure. This includes maintaining the processing chamber 414, and the first wafer transfer module at the vacuum or low pressure. The second wafer transfer module may be at a different pressure, such as atmospheric. As the wafer is transferred throughout the tool 400, it is therefore maintained at the vacuum or low pressure.

In a further example, a substrate is placed in one of the FOUPs 408 and the second robot arm unit 406, or front-end robot, transfers the substrate from the FOUP 418 to an aligner, which allows the substrate to be properly centered before it is etched, or deposited upon, or otherwise processed. After being aligned, the substrate is moved by the second robot arm unit 406 into the airlock module 404. Because airlock modules have the ability to match the environment between an ATM and a VTM, the substrate is able to move between the two pressure environments without being damaged. From the airlock module 404, the substrate is moved by the first robot arm unit 426 through the first wafer transfer module, or VTM, and into the processing chamber 414. In order to achieve this substrate movement, the first robot arm unit 426 uses end effectors on each of its arms.

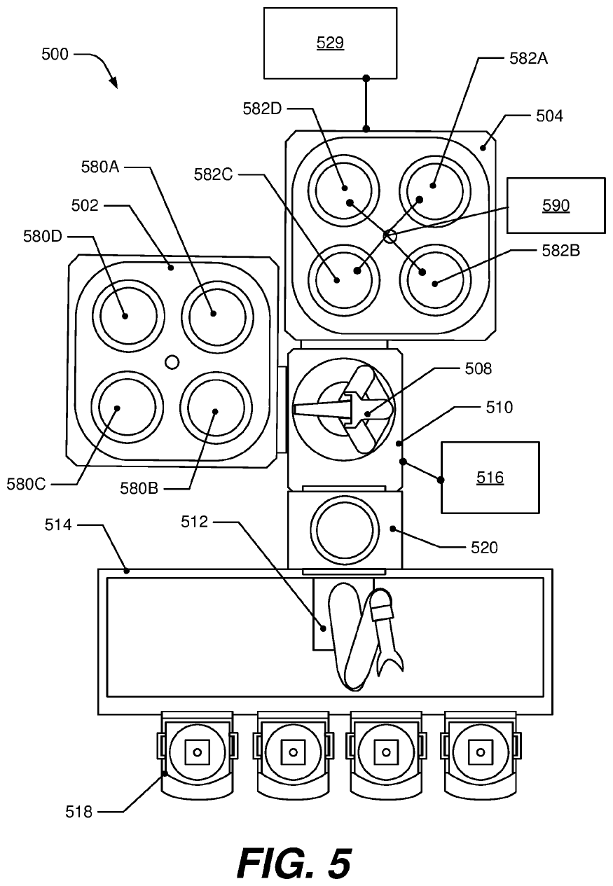

FIG. 4 also depicts an embodiment of a system controller 450 employed to control process conditions and hardware states of process tool 400. System controller 450 may include one or more memory devices 456, one or more mass storage devices 454, and one or more processors 452. Processor 452 may include a CPU or computer 458, analog and/or digital input/output connections, stepper motor controller boards, etc. In some embodiments, system controller 450 includes machine-readable instructions for performing operations such as those described above with respect to FIG. 4 and below with respect to FIG. 5.

As described above, one or more process stations may be included in a multi-station processing tool. FIG. 5 depicts an example processing apparatus according to disclosed embodiments. Tool 500 includes a first processing chamber 502 and a second processing chamber 504. The first processing chamber 502 includes a plurality of processing stations, four stations 580A-D, that each may process a wafer. The first processing chamber 502 is configured to perform plasma treatment operations on the wafers. The second processing chamber 504 is configured to perform deposition on the wafer and may be considered a deposition chamber. The second processing chamber 504 also includes a plurality of processing stations, four stations 582A-D, that each may process a wafer and may be controlled by a module 590. The first and second processing chambers 502 and 504 may be considered multi-station processing chambers.

Tool 500 also includes a wafer transfer unit configured to transport one or more wafers within the tool 500. Additional features of tool 500 will be discussed in greater detail below, and various features are discussed here with respect to some of the described techniques. In the depicted illustration, the wafer transfer unit includes a first robotic arm unit 508 in a first wafer transfer module 510 and a second robotic arm unit 512 in a second wafer transfer module 514 that may be considered an equipment front end module (EFEM) configured to received containers for wafers, such as a front opening unified module (FOUP) 516. The first robotic arm unit 508 is configured to transport a wafer between the first processing chamber 502 and the second processing chamber 504, and between the first processing chamber 502 and the second robotic arm unit 512. The second robotic arm unit 512 is configured to transport the wafer between a FOUP and the first robotic arm unit 508. After a wafer has been treated in the first processing chamber 502, the wafer transfer unit is able to transfer the wafer from the first processing chamber 502, to the second processing chamber 504 where one or more layers of encapsulation material may be deposited on one or more wafers.

Similar to above, the first wafer transfer module 510 may a vacuum transfer module (VTM). Airlock 520, also known as a loadlock or transfer module, is shown and may be individually optimized to perform various fabrication processes. The tool 500 also includes a FOUP 516 that is configured to lower the pressure of the tool 500 to a vacuum or low pressure, e.g., between about 1 mTorr and about 10 Torr, and maintain the tool 500 at this pressure. This includes maintaining the first and second processing chambers 502 and 504, and the first wafer transfer module 510 at the vacuum or low pressure. The second wafer transfer module 514 may be at a different pressure, such as atmospheric. As the wafer is transferred throughout the tool 500, it is therefore maintained at the vacuum or low pressure. For example, as the wafer is transferred from the first processing chamber 502, into the first wafer transfer module 510, and to the second processing chamber 504, the wafer is maintained at the vacuum or low pressure and not exposed to atmospheric pressure.

In a further example, a substrate is placed in one of the FOUPs 518 and the second robot arm unit 512, or front-end robot, transfers the substrate from the FOUP 518 to an aligner, which allows the substrate to be properly centered before it is etched, or deposited upon, or otherwise processed. After being aligned, the substrate is moved by the second robot arm unit 512 into the airlock 520. Because airlock modules have the ability to match the environment between an ATM and a VTM, the substrate is able to move between the two pressure environments without being damaged. From the airlock 520, the substrate is moved by the first robot arm unit 508 through the first wafer transfer module 510, or VTM 510, and into the first processing chamber 502. In order to achieve this substrate movement, the first robot arm unit 508 uses end effectors on each of its arms.

FIG. 5 also depicts an embodiment of a system controller 529 employed to control process conditions and hardware states of tool 500. System controller 529 may include one or more memory devices (not shown), one or more mass storage devices (not shown), and one or more processors (not shown). Processors may include a CPU or computer, analog, and/or digital input/output connections, stepper motor controller boards, etc.

In some embodiments, system controller 529 controls all of the activities of tool 500. System controller 529 executes system control software stored in mass storage device, loaded into memory device, and executed on processor. Alternatively, the control logic may be hard coded in the system controller 529. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software may include instructions for controlling the timing, mixture of gases, gas flow rates, chamber and/or station pressure, chamber and/or station temperature, wafer temperature, target power levels, RF power levels, substrate pedestal, chuck and/or susceptor position, and parameters of a particular process performed by tool 500. System control software may be configured in any suitable way. For example, various process tool component subroutines or control objects may be written to control operation of the process tool components used to carry out various process tool processes. System control software may be coded in any suitable computer readable programming language.

In some embodiments, system control software may include input/output control (IOC) sequencing instructions for controlling the various parameters described above. Other computer software and/or programs stored on mass storage device and/or memory device associated with system controller 529 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal and to control the spacing between the substrate and other parts of tool 500.

A process gas control program may include code for controlling gas composition (e.g., silicon-containing precursor gases, nitrogen-containing gases, carrier gases, inert gases, and/or purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium or nitrogen) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 529. The user interface may include a display screen, graphical software displays of the apparatus and/or process conditions, and user input devices such as pointing devices, keyboards, touch screens, microphones, etc.

In some embodiments, parameters adjusted by system controller 529 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 529 from various process tool sensors. The signals for controlling the process may be output on the analog and digital output connections of tool 500. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 529 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 529 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 529.

In some implementations, the system controller 529 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 529, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 529 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 529 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 529, in some implementations, may be a part of or coupled to a computer that is integrated with, coupled to the system, otherwise networked to the system, or a combination thereof. For example, the system controller 529 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 529 receives instructions in the form of data, which specify parameters for each of the processing steps to be performed during one or more operations. It should be understood that the parameters may be specific to the type of process to be performed and the type of tool that the system controller 529 is configured to interface with or control. Thus as described above, the system controller 529 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 529 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

An appropriate apparatus for performing the methods disclosed herein is further discussed and described in U.S. patents application Ser. Nos. 13/084,399 (now U.S. Pat. No. 8,728,956), filed Apr. 11, 2011, and titled “PLASMA ACTIVATED CONFORMAL FILM DEPOSITION”; and Ser. No. 13/084,305, filed Apr. 11, 2011, and titled “SILICON NITRIDE FILMS AND METHODS,” each of which is incorporated herein in its entireties.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### EXPERIMENTAL

### Experiment 1

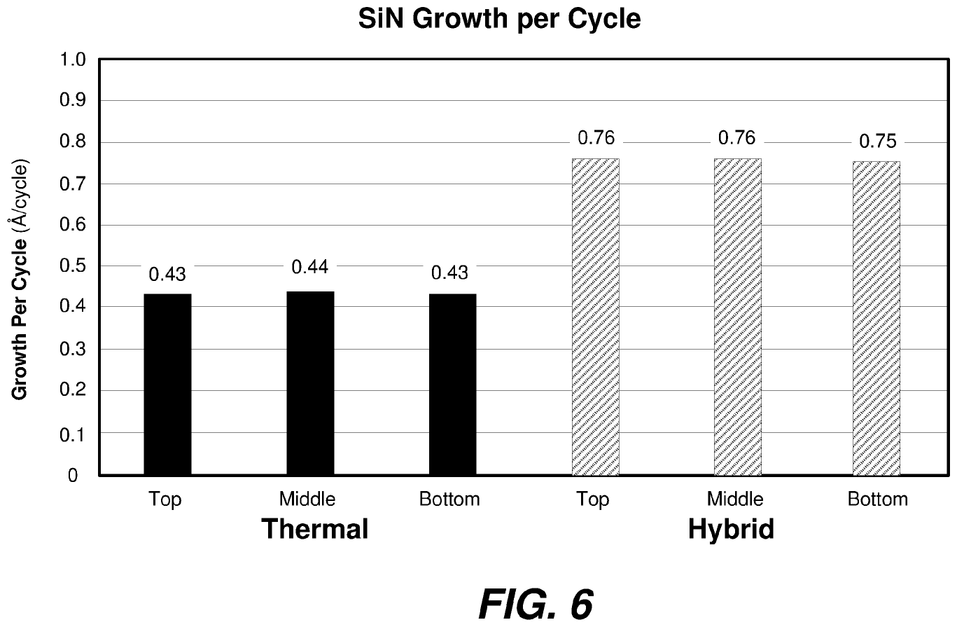

Silicon nitride was deposited onto substrates having high aspect ratio features subject to thermal atomic layer deposition (ALD) and hybrid ALD in accordance with certain disclosed embodiments. For thermal ALD, silicon nitride was deposited by exposing the substrate to one or more deposition cycles, each deposition cycle including: a silicon-containing precursor dose, purge, ammonia thermal conversion, and purge. For hybrid ALD, silicon nitride was deposited by exposing the substrate to one or more deposition cycles, each deposition cycle including: a silicon-containing precursor dose, purge, ammonia thermal conversion, purge, ammonia and nitrogen plasma exposure, and purge. The thickness of the sidewall of deposited silicon nitride film was measured at the top of the feature near the opening at a depth of about 0.5 μm, in the middle using a planar cut TEM, and at the bottom measured 0.5 μm from the bottom of the feature. The growth per cycle for the top, middle, and bottom were measured and are graphed in FIG. 6. FIG. 6 shows an increase in the growth rate on sidewalls of the feature when the hybrid ALD process is used, showing at least a 1.7 times greater growth rate. Conformality appears to be about 100%.

### Experiment 2

An FTIR was taken of silicon nitride deposited by thermal ALD and silicon nitride deposited by hybrid ALD. For thermal ALD, silicon nitride was deposited by exposing the substrate to one or more deposition cycles, each deposition cycle including: a silicon-containing precursor dose, purge, ammonia thermal conversion, and purge. For hybrid ALD, silicon nitride was deposited by exposing the substrate to one or more deposition cycles, each deposition cycle including: a silicon-containing precursor dose, purge, ammonia thermal conversion, purge, ammonia and nitrogen plasma exposure, and purge.

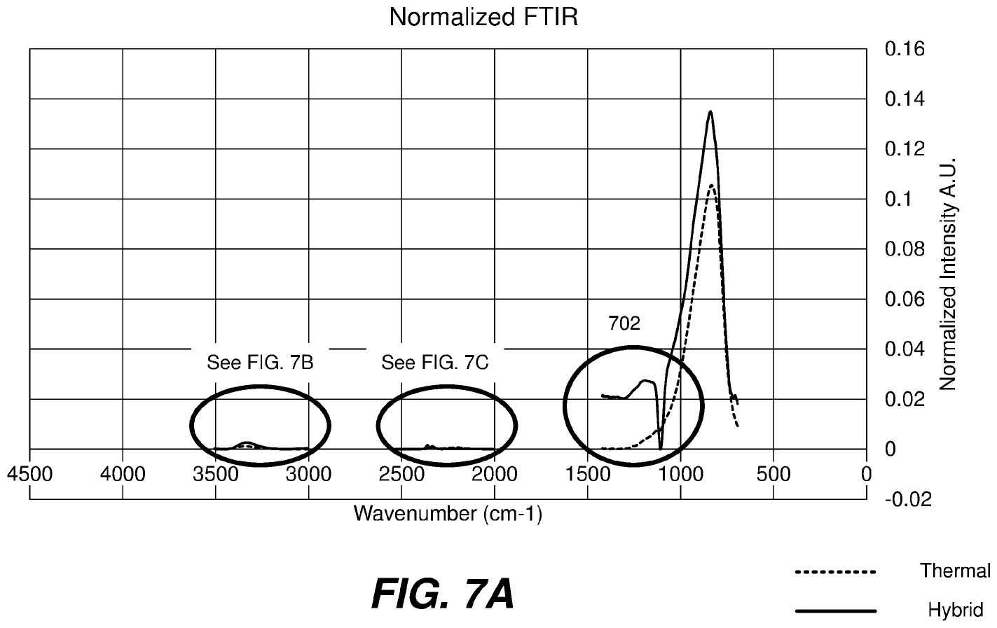

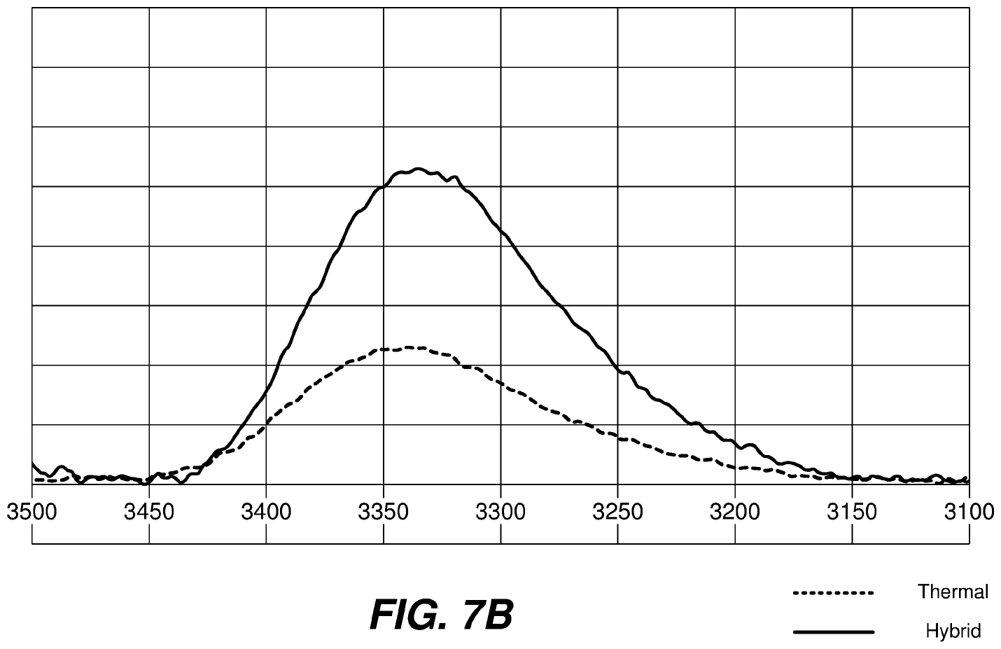

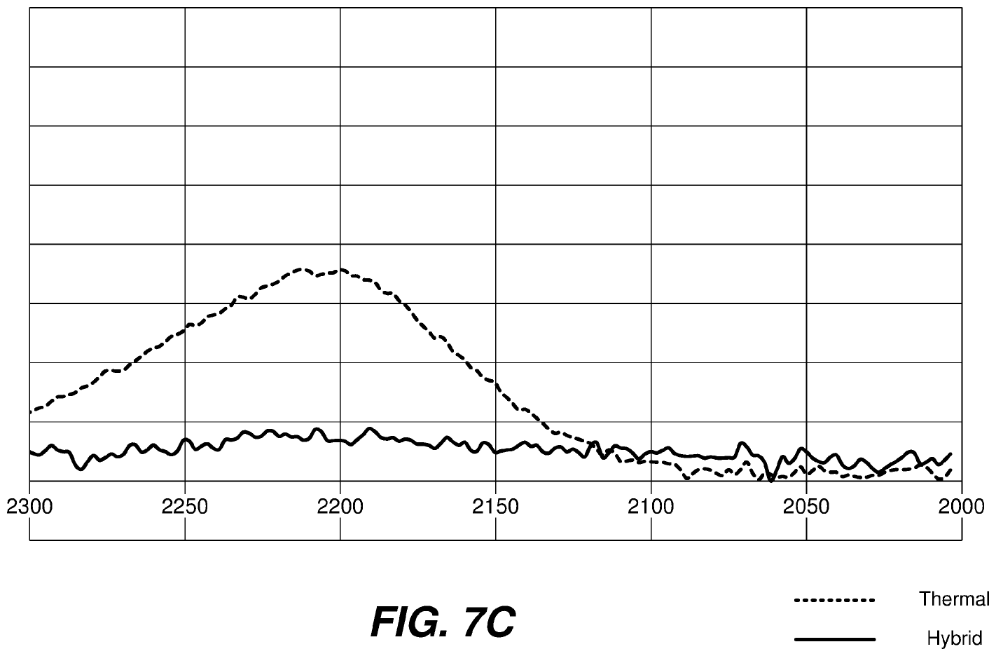

The FTIR are depicted in FIGS. 7A, 7B (for a zoomed in section near the 3000-3500 wavenumber region), and 7C (for a zoomed in section near the 2000-2500 wave number region).

The circle 702 is depicted to show that while the hybrid ALD silicon nitride generally had more Si—N bonds (see peak around 800 cm⁻¹), the FTIR showed some variation at 702 due to Si—N from the substrate itself and is an artifact.

FIG. 7B shows a 40× zoom on the section circled in FIG. 7A. Silicon nitride deposited by hybrid ALD exhibited a higher concentration of N—H bonds compared to silicon nitride deposited by thermal ALD.

FIG. 7C shows a 100× zoom on the section circled in FIG. 7A. Silicon nitride deposited by hybrid ALD exhibited a lower concentration of Si—H bonds compared to silicon nitride deposited by thermal ALD.

These results suggest thermal ALD results in H bonded with Si and N, whereas hybrid ALD may tend to form H bonds mostly with N. In some embodiments, Si—H bonds may be shallow, low energy electron traps which may have be useful in some applications. In some cases, control of the concentration of Si—H bonds in deposited silicon nitride may be used for high energy trap states. Varying the RF plasma exposure during hybrid ALD can help tune how hydrogen is bonded in the deposited film.

### Experiment 3

Roughness was evaluated for a silicon nitride film deposited by thermal ALD and silicon nitride deposited by hybrid ALD. For thermal ALD, silicon nitride was deposited by exposing the substrate to one or more deposition cycles, each deposition cycle including: a silicon-containing precursor dose, purge, ammonia thermal conversion, and purge. For hybrid ALD, silicon nitride was deposited by exposing the substrate to one or more deposition cycles, each deposition cycle including: a silicon-containing precursor dose, purge, ammonia thermal conversion, purge, ammonia and nitrogen plasma exposure, and purge.

The film roughness in thermal ALD silicon nitride had an rms of 0.232 nm and mean of 0.179 nm. The film roughness in hybrid ALD silicon nitride had an rms of 0.179 nm and a mean of 0.135 nm.

These results suggest film roughness decreased when the hybrid ALD process was used as compared to a thermal ALD process.

### Experiment 4

Impurities were measured for a silicon nitride film deposited by thermal ALD and silicon nitride deposited by hybrid ALD. For thermal ALD, silicon nitride was deposited by exposing the substrate to one or more deposition cycles, each deposition cycle including: a silicon-containing precursor dose, purge, ammonia thermal conversion, and purge. For hybrid ALD, silicon nitride was deposited by exposing the substrate to one or more deposition cycles, each deposition cycle including: a silicon-containing precursor dose, purge, ammonia thermal conversion, purge, ammonia and nitrogen plasma exposure, and purge.

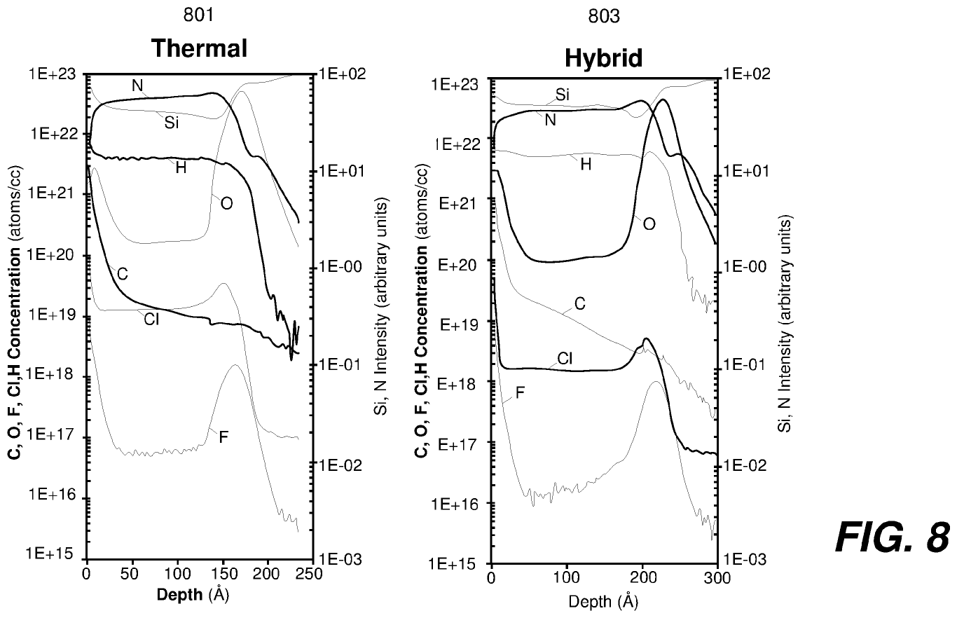

FIG. 8 shows results for thermal ALD at 801 and hybrid ALD at 803. The results suggest a reduced concentration of F and Cl impurities in hybrid ALD as compared to thermal ALD. Chlorine may be present due to use of a chlorine-containing silicon-containing precursor. Fluorine may be present due to chamber cleaning by using nitrogen trifluoride.

Table 1 shows a comparison of the concentration of C, O, F, Cl, and H in thermal ALD silicon nitride and hybrid ALD silicon nitride as measured by secondary ion mass spectroscopy (SIMS).

TABLE 1
Reduction in Concentration of Carbon, Oxygen,
Fluorine, Chlorine, and Hydrogen in SiN deposited
by Thermal ALD only and Hybrid ALD

| | | Thermal | Hybrid | % reduction |
|---|---|---|---|---|
| SIMS | C | 1.34E+19 | 8.75E+18 | 35% |
| | O | 1.79E+20 | 1.14E+20 | 36% |
| | F | 6.07E+16 | 2.19E+16 | 64% |
| | Cl | 1.43E+19 | 1.6E+18 | 89% |
| | H | 4.25E+21 | 5.75E+21 | −35% |

While hydrogen showed an increase in hybrid ALD silicon nitride, it may be due to the hydrogen being bonded differently in the silicon nitride as compared to thermal ALD silicon nitride. The other elements show a reduction in impurities.

### Experiment 5

Growth per cycle as a function of pedestal temperature was measured for a silicon nitride film deposited by thermal ALD and silicon nitride deposited by hybrid ALD. For thermal ALD, silicon nitride was deposited by exposing the substrate to one or more deposition cycles, each deposition cycle including: a silicon-containing precursor dose, purge, ammonia thermal conversion, and purge. For hybrid ALD, silicon nitride was deposited by exposing the substrate to one or more deposition cycles, each deposition cycle including: a silicon-containing precursor dose, purge, ammonia thermal conversion, purge, ammonia and nitrogen plasma exposure, and purge.

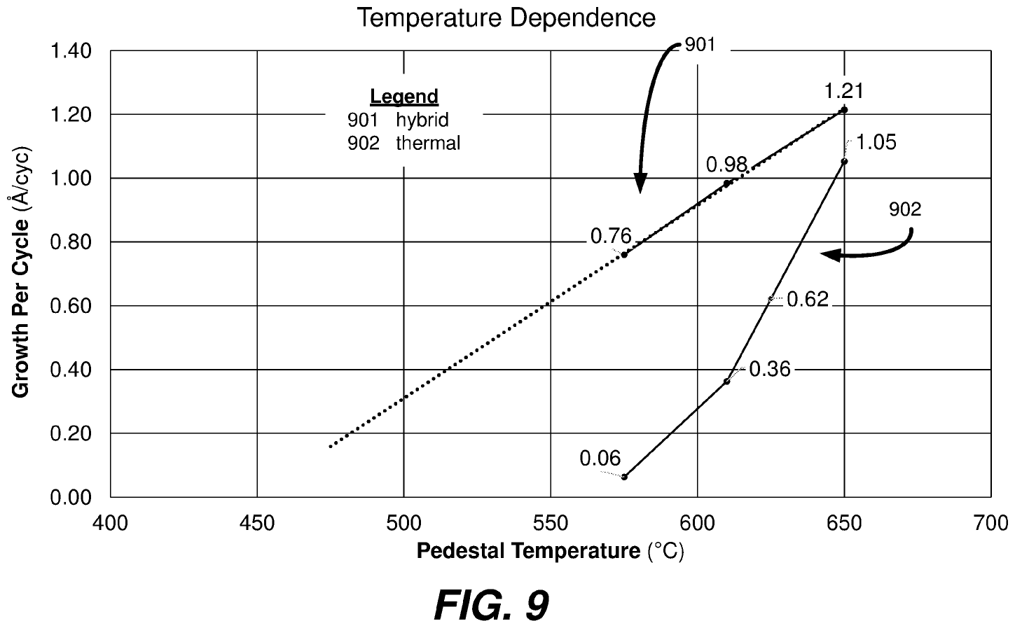

The results are in FIG. 9. Data 901 shows the temperature dependence for hybrid ALD and data 902 shows the temperature dependence for thermal only ALD. The growth rate changes substantially with change in pedestal temperature in thermal only ALD, whereas hybrid ALD shows a gradual increase in growth per cycle over varying increased pedestal temperature.

### Experiment 6

Film thickness and within-wafer uniformity was evaluated for a silicon nitride film deposited by thermal ALD and silicon nitride deposited by hybrid ALD. For thermal ALD, silicon nitride was deposited by exposing the substrate to one or more deposition cycles, each deposition cycle including: a silicon-containing precursor dose, purge, ammonia thermal conversion, and purge. For hybrid ALD, silicon nitride was deposited by exposing the substrate to one or more deposition cycles, each deposition cycle including: a silicon-containing precursor dose, purge, ammonia thermal conversion, purge, ammonia and nitrogen plasma exposure, and purge.

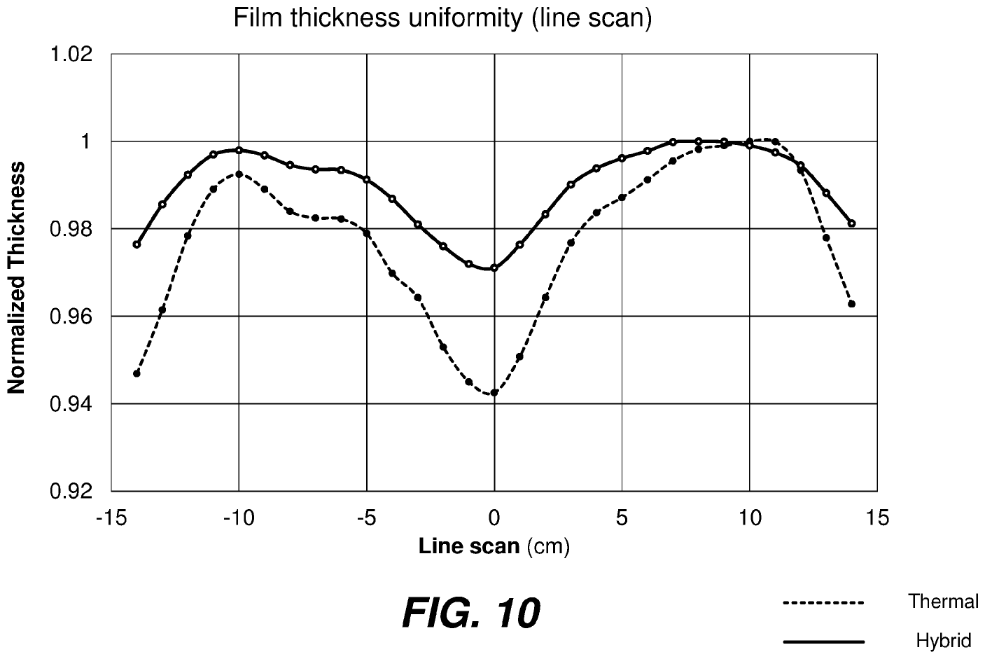

The results are in FIG. 10. The solid line for hybrid ALD shows that the relative within-wafer non-uniformity was reduced (e.g., a flatter line in this line scan is shown and the non-uniformity was about 3%) as compared to silicon nitride deposited by thermal-only ALD where the non-uniformity was about 6%. The uniformity decreased by over 50% as compared to thermal-only conversion.

### Experiment 7

Density, wet etch rate in 100:1 dilute hydrofluoric acid, and stress were evaluated for a silicon nitride film deposited by thermal ALD and silicon nitride deposited by hybrid ALD. For thermal ALD, silicon nitride was deposited by exposing the substrate to one or more deposition cycles, each deposition cycle including: a silicon-containing precursor dose, purge, ammonia thermal conversion, and purge. For hybrid ALD, silicon nitride was deposited by exposing the substrate to one or more deposition cycles, each deposition cycle including: a silicon-containing precursor dose, purge, ammonia thermal conversion, purge, ammonia and nitrogen plasma exposure, and purge.

The results are in Table 2 below. These show that stress can be tuned by changing plasma time and that tensile to compressive films may be achieved by modulating process conditions, and that the density increased and wet etch rate decreased when hybrid ALD was used, suggesting improvement in film quality.

TABLE 2
Density, Wet Etch Rate, and Stress of Hybrid ALD Silicon
Nitride and Thermal-only ALD Silicon Nitride

| | | Thermal ALD | Hybrid ALD |
|---|---|---|---|
| Density (g/cc) | XRR | 2.843 | 2.909 |
| WER (A/min)- 100:1 DHF | Ellipsometry | 2.02 | 1.26 |
| Stress | Ellipsometry | 615 Mpa | −406 Mpa |

### Experiment 8

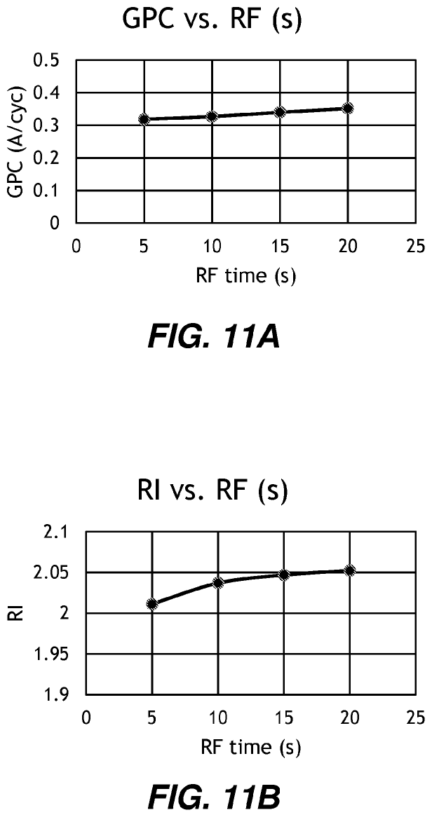

Growth of an undercoat film deposited as a blanket film was evaluated. A film was deposited at 650° C. using 100 atomic layer deposition cycles, where each cycle involved flowing 100 sccm diisopropylaminosilane for 1 second at 3 Torr, followed by purging for 3 seconds, followed by flowing 20 slm of nitrogen gas at 3 Torr and igniting a plasma at 6000 W for 5 seconds (then 10 seconds, then 15 seconds, then 20 seconds, to evaluate variable time), followed by purging for 3 seconds. FIG. 11A shows a trend for the growth per cycle versus plasma on time. FIG. 11B shows a trend for refractive index versus plasma on time. Refractive index saturation was observed at about 20 seconds.

### Experiment 9

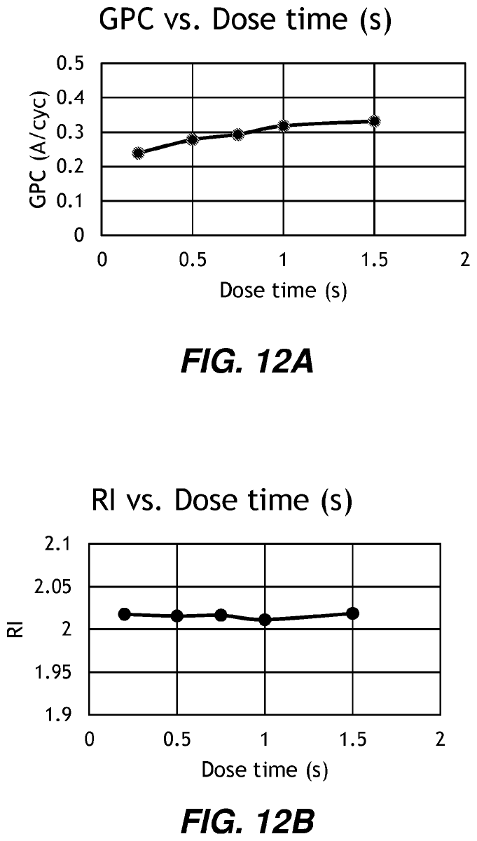

Growth of an undercoat film deposited as a blanket film was evaluated. A film was deposited at 650° C. using 100 atomic layer deposition cycles, where each cycle involved flowing 100 sccm diisopropylaminosilane for variable time in seconds at 3 Torr, followed by purging for 3 seconds, followed by flowing 20 slm of nitrogen gas at 3 Torr and igniting a plasma at 6000 W for 5 seconds, followed by purging for 3 seconds. FIG. 12A shows a trend for the growth per cycle versus dose time. FIG. 12B shows a trend for refractive index versus dose time. Sub-saturation of dose time occurred within about 1.5 seconds.

### Experiment 10

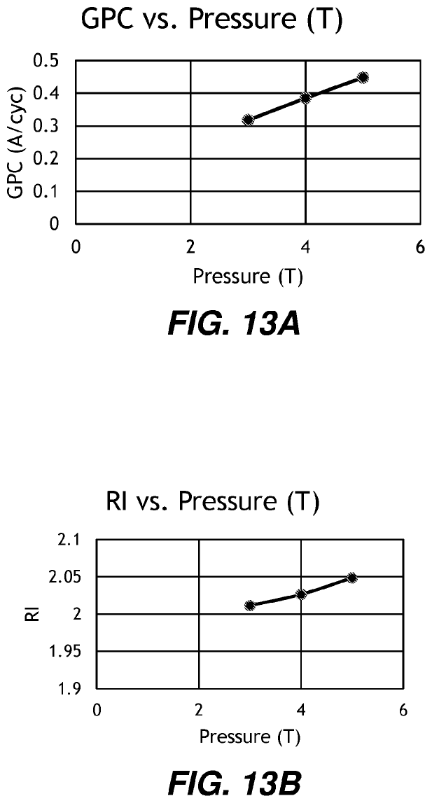

Growth of an undercoat film deposited as a blanket film was evaluated. A film was deposited at 650° C. using 100 atomic layer deposition cycles, where each cycle involved flowing 100 sccm diisopropylaminosilane for 1 second at variable pressure, followed by purging for 3 seconds, followed by flowing 20 slm of nitrogen gas at variable pressure and igniting a plasma at 6000 W for 5 seconds, followed by purging for 3 seconds. FIG. 13A shows a trend for the growth per cycle versus pressure. FIG. 13B shows a trend for refractive index versus pressure. As pressure increased, growth and refractive index also increased. Overall, growth per cycle of about 0.45 Å/cycle with a refractive index of about 2.05 was achieved with less than about 10 seconds cycle time.

### Experiment 11

A Fourier-transform infrared spectroscopy (FTIR) spectrum for a non-graded SiON film and an FTIR spectrum for a silicon oxide film were obtained. The refractive index of the silicon oxide film was 1.46. The refractive index of the SiON film was 1.63. The FTIR peak shift to lower wavenumber indicates an increased amount of nitrogen in the film.

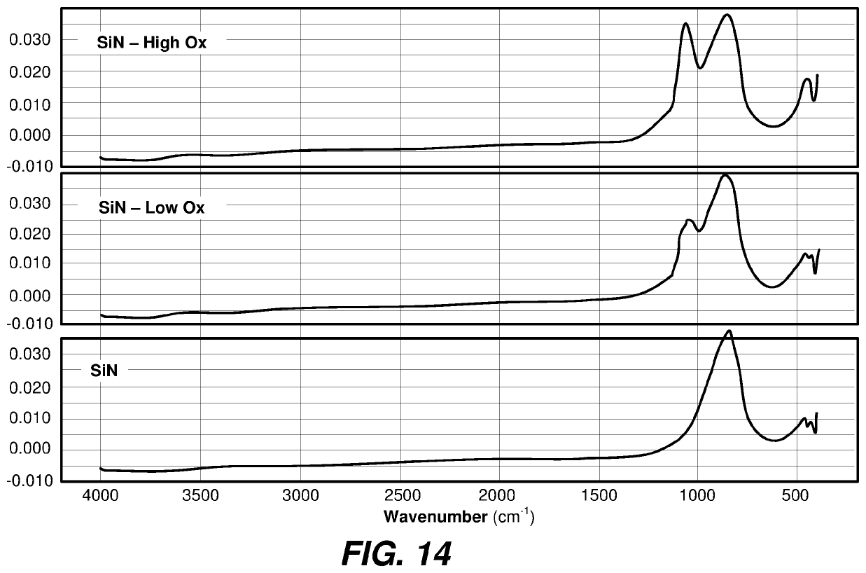

An FTIR spectrum for a non-graded silicon nitride film, a graded silicon nitride film with in-situ oxidation for 10 minutes, and a graded silicon nitride film with in-situ oxidation for 15 minutes were obtained. The results are in FIG. 14; the bottom graph shows the non-graded silicon nitride film, the center graph shows the graded silicon nitride film with in-situ oxidation for 10 minutes, and the top graph shows the graded silicon nitride film with in-situ oxidation for 15 minutes. The peaks show the bending mode of Si—O bonds. For graded SiON films, both the SiN and SiO peaks are visible. Longer in-situ oxidation increased the Si—O peak, suggesting that more oxygen was incorporated and more Si—O—Si bonds were formed, which means there is deeper oxidation of the SiN film. These results suggest that the amount of oxidation and the depth of oxidation can be controlled using certain disclosed embodiments.

### Experiment 12

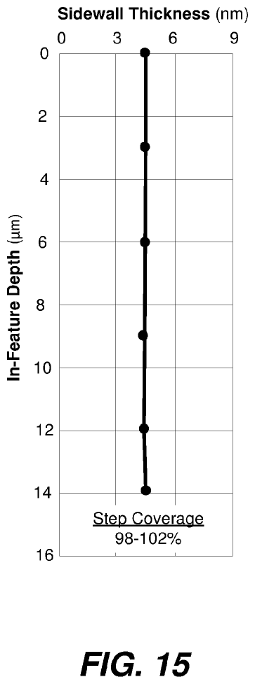

An experiment was conducted that measured the sidewall thickness as compared to in-feature depth of silicon oxynitride deposited using certain disclosed embodiments. The step coverage achieved was about 90% to about 102% as shown in FIG. 15.

### Definitions and Precursors

### Definitions

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O) H), acetyl (Ac or —C(O) Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O) Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O) H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which Lis C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkenylene or alkynylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N³); (16) cyano (e.g., —CN); (17) C₁₋₆ azidoalkyl (e.g., -L-N₃, in which L is C₁₋₆ alkyl); (18) aldehyde (e.g., —C(O) H); (19) aldehyde-C₁₋₆ alkyl (e.g., -L-C(O) H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L′ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO) (R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O) NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{AK}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66 (1): 1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

As used herein, the term “about” means+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### Silicon-Containing Precursors

In various embodiments, the silicon-containing precursor is a silane. Silanes include but are not limited to substituted and unsubstituted silanes, halosilanes, aminosilanes, organosilanes, alkylsilanes, alkylaminosilanes, and alkylhalosilanes. In particular embodiments, the silicon-containing precursor includes a halosilane precursor. In particular embodiments, the silicon-containing precursor includes an aminosilane precursor.

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino) silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino) silane (DSBAS), di(isopropylamino) silane (DIPAS), bis(diethylamino) silane (BDEAS), and the like. A further example of an aminosilane is trisilylamine (N(SiH₃)₃). In one example, the silicon-containing precursor is DIPAS. In another example, the silicon-containing precursor is BTBAS.

A silicon-containing precursor can include one or more optionally substituted amino groups, thereby providing a non-limiting amino silane. In one embodiment, the precursor has a formula of (R′)₄₋ₓSi(NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″₂N)ₓ(R′)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″₂) attached to one or more silicon atoms.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O) H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}; —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R′ group attached to the silicon atom. In one embodiment, the precursor has a formula of (R′)(H)₃₋ₓSi(NR″₂)ₓ, wherein R′ and R″ can be any described herein, and wherein x is 1, 2, or 3. In another embodiment, the precursor has a formula of (R′)(H)₂Si(NR″₂), wherein R′ and R″ can be any described herein. In one embodiment, the precursor has a formula of (R′)(H)Si(NR″₂)₂, wherein R′ and R″ can be any described herein. In another embodiment, the precursor has a formula of (R′)₂(H)Si(NR″₂), wherein R′ and R″ can be any described herein. In yet another embodiment, the precursor has a formula of (R′)₂Si(NR″₂)₂, wherein R′ and R″ can be any described herein. In one embodiment, the precursor has a formula of (R′)₃Si(NR″₂), wherein R′ and R″ can be any described herein.

The precursor can lack an R′ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂)ₓ, wherein each R″ can independently be any described herein. In particular embodiments, each R″ is, independently, aliphatic, heteroaliphatic, aromatic, or heteroaromatic.

The precursor can include one or more hydrogen atoms attached to the silicon atom. In one embodiment, the precursor has a formula of (H)₃Si(NR″₂) or (H)₂Si(NR″₂)₂ or (H) Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The precursor can include a heterocyclyl group having a nitrogen atom. In one embodiment, the formula has a formula of H₃Si-Het, in which Het is an optionally substituted heterocyclyl including at least one nitrogen atom. In particular embodiments, the precursor has a formula of

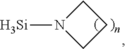

in which the heterocyclyl group can be optionally substituted (e.g., with any substituent described herein as a substitution for alkyl), and wherein n is 1, 2, 3, 4, or 5. In one embodiment, the formula has a formula of R′₃Si-Het, in which Het is an optionally substituted heterocyclyl including at least one nitrogen atom, and each R′ can independently be any described herein. In particular embodiments, the precursor has a formula of

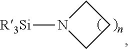

in which the heterocyclyl group can be optionally substituted (e.g., with any substituent described herein as a substitution for alkyl); each R′ can independently be any described herein; and wherein n is 1, 2, 3, 4, or 5.

In some instances, the precursor can have two or more silicon atoms, in which the precursor can include a Si—Si bond. In a particular embodiment, the precursor has a formula of (R″₂N)ₓ(R′)₃₋ₓSi—Si(R′)₃₋ₓ(NR″₂)ₓ, wherein R′ and R″ can be any described herein. In one embodiment, the precursor has a formula of (R″₂N)(R′)₂Si—Si(R′)₂(NR″₂), wherein R′ and R″ can be any described herein. In another embodiment, the precursor has a formula of (R″₂N)₂(R′)Si—Si(R′)(NR″₂)₂, wherein R′ and R″ can be any described herein. In yet another embodiment, the precursor has a formula of (R″₂N)₃Si—Si(NR″₂)₃, wherein each R″ can independently be any described herein.

The precursor can include differing groups attached to the silicon atoms. In one instance, the precursor has a formula of (R″₂N)ₓ(R′)₃₋ₓSi—SiH₃, wherein R′ and R″ can be any described herein.

A linker can be present between two silicon atoms. In one instance, the precursor has a formula of (R″₂N)ₓ(R′)₃₋ₓSi—NR—Si(R′)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the precursor has a formula of (R″₂N)ₓ(H)₃₋ₓSi—NR—Si(H)₃₋ₓ(NR″₂)ₓ, wherein R, R′, and R″ can be any described herein.

The precursor can include a combination of R′ groups with a linker having a heteroatom. In one instance, the precursor has a formula of (R′)₃Si—NR—Si(R′)₃, wherein R and R′ can be any described herein. In another instance, the precursor has a formula of (R′)₃Si-L-Si(R′)₃, wherein L and R′ can be any described herein. In particular embodiments, L is oxy (—O—), optionally substituted imino (e.g., —NR—), or optionally substituted silyl (e.g., —SiR₂—).

The precursor can include any useful combination of R′ and NR″₂ groups in combination with two silicon atoms. In one instance, the precursor has a formula of (R″₂N)(R′)₂Si-L-Si(R′)₂(NR″₂)ₓ, wherein L, R′, and R″ can be any described herein.

The precursor can include heterocyclic groups including the silicon and nitrogen atoms. In one embodiment, the precursor has a formula of

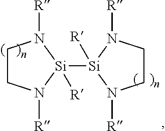

wherein R′ and R″ can be any described herein, and wherein n is 1, 2, 3, or 4.

In another embodiment, the precursor has a formula of

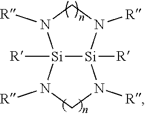

wherein R′ and R″ can be any described herein, and wherein n is 1, 2, 3, or 4. In yet another embodiment, the precursor has a formula of

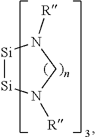

in which each R″ can independently be any described herein; and wherein n is 1, 2, 3, or 4.

In another embodiment, the precursor has a formula of

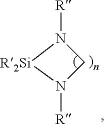

wherein R′ and R″ can be any described herein, and wherein n is 1, 2, 3, or 4. In yet another embodiment, the precursor has a formula of

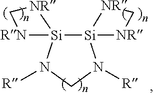

wherein R″ can independently be any described herein, and wherein n is 1, 2, 3, or 4.

In any precursor herein, two R″ can be taken together, with the nitrogen atom to which each is attached, to form an optionally substituted heterocyclyl.

Precursors can include any of the following, e.g., (R^{Ak})Si(NH₂)(NR^{Ak}₂)₂, (R^{Ak})Si(NR^{Ak}₂)₃, (R^{Ak})₂Si(NHR^{Ak}₂), (R^{Ak})(H)Si(NHR^{Ak})₂, (R^{Ak})₂Si(NR^{Ak}), (R^{Ak})₃Si(NHR^{Ak}), H₂Si(NHR^{Ak}₂)₂, (R^{Ak})(H)Si(NR^{Ak}₂)₂, HSi(NH₂) (NR^{Ak}₂)₂, HSi(NR^{Ak}₂)₃, Si(NR^{Ak}₂)₄, (R′)(H)Si(NR″₂)₂, (R′)₂Si(NR^{Ak}₂)₂, (R′)₂Si(N [SiH₃]₂)₂, (R′)₂Si(N[SiR″₃]₂)₂, or (R′)₃Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{Ak} is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of precursor include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe₃[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane (SiHEt₂[NEt₂]); diethylaminotrimethylsilane (SiMe₃[NEt₂]); diethylaminotriethylsilane (SiEt₃[NEt₂]); iso-propylaminodimethylsilane (SiHMe₂[NHiPr]); iso-propylaminotrimethylsilane (SiMe₃[NHiPr]); iso-propylaminodiethylsilane (SiHEt₂[NHiPr]); iso-propylaminotriethylsilane (SiEt₃[NHiPr]); di-isopropylaminotrimethylsilane (SiMe₃[NiPr₂]); di-iso-propylaminosilane (SiH₃[NiPr₂], C₆H₁₇NSi, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPr₂]); di-isopropylaminotriethylsilane (SiEt₃[NiPr₂]); n-propylaminotrimethylsilane (SiMe₃[NHnPr]); di-sec-butylaminosilane (SiH₃[NsBu₂] or DSBAS); di-sec-butylaminomethylsilane (SiH₂Me[NsBu₂]); iso-butylaminotrimethylsilane (SiMe₃[NHiBu]); n-butylaminotrimethylsilane (SiMe₃[NHnBu]); tert-butylaminodimethylsilane (SiHMe₂[NHtBu]); tert-butylaminotrimethylsilane (SiMe₃[NHtBu]); tert-butylaminodiethylsilane (SiHEt₂[NHtBu]); tert-butylaminotriethylsilane (SiEt₃[NHtBu]); dicyclohexylaminosilane (SiH₃[NCy₂], in which Cy is cyclohexyl); N-propylisopropylaminosilane (SiH₃[NiPrnPr]); N-methylcyclohexylaminosilane (SiH₃[NMeCy]); N-ethylcyclohexylaminosilane (SiH₃[NEtCy]); allylphenylaminosilane (SiH₃[NAllPh]); N-isopropylcyclohexylaminosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₃[NHPyr], in which Pyr is pyrrolindyl); piperidino trimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidazolyl); bis(dimethylamino) silane (SiH₂[NMe₂]₂ or BDMAS); bis(dimethylamino) methylsilane (SiMeH[NMe₂]₂); bis(dimethylamino)dimethylsilane (SiMe₂[NMe₂]₂ or BDMADMS); bis(dimethylamino) diethylsilane (SiEt₂[NMe₂]₂); bis(dimethylamino) methylvinylsilane (SiMeVi[NMe₂]₂); bis(ethylamino)dimethylsilane (SiMe₂[NHEt]₂); bis(ethylmethylamino) silane (SiH₂[NMeEt]₂); bis(ethylmethylamino)dimethylsilane (SiMe₂[NMeEt]₂); bis(ethylmethylamino) diethylsilane (SiEt₂[NMeEt]₂); bis(ethylmethylamino) methylvinylsilane (SiMeVi[NMeEt]₂); bis(diethylamino) silane (SiH₂[NEt₂]₂, C₈H₂₂N₂Si, or BDEAS); bis(diethylamino)dimethylsilane (SiMe₂[NEt₂]₂); bis(diethylamino)methylvinylsilane (SiMeVi[NEt₂]₂); bis(diethylamino) diethylsilane (SiEt₂[NEt₂]₂); bis(iso-propylamino) dimethylsilane (SiMe₂[NHiPr]₂); bis(iso-propylamino) diethylsilane (SiEt₂[NHiPr]₂); bis(iso-propylamino) methylvinylsilane (SiMeVi[NHiPr]₂); bis(di-iso-propylamino) silane (SiH₂[NiPr₂]₂); bis(di-iso-propylamino)dimethylsilane (SiMe₂[NiPr₂]₂); bis(di-iso-propylamino) diethylsilane (SiEt₂[NiPr₂]₂); bis(di-iso-propylamino)methylvinylsilane (SiMeVi[NiPr₂]₂); bis(methylamino) silane (SiH₂[NHMe]₂); bis(sec-butylamino) silane (SiH₂[NHsBu]₂); bis(sec-butylamino) methylsilane (SiHMe[NHsBu]₂); bis(sec-butylamino)ethylsilane (SiHEt[NHsBu]₂); bis(tert-butylamino) silane (SiH₂[NHtBu]₂ or BTBAS); bis(tert-butylamino)dimethylsilane (SiMe₂[NHtBu]₂); bis(tert-butylamino) methylvinylsilane (SiMeVi[NHtBu]₂); bis(tert-butylamino) diethylsilane (SiEt₂[NHtBu]₂); bis(1-imidazolyl)dimethylsilane (SiMe₂[Im]₂, in which Im is imidazolyl); tris(dimethylamino) silane (SiH[NMe₂]₃ or 3DMAS); tris(dimethylamino)phenylsilane (SiPh[NMe₂]₃); tris(dimethylamino) methylsilane (SiMe[NMe₂]₃); tris(dimethylamino)ethylsilane (SiEt[NMe₂]₃); tris(ethylmethylamino) silane (SiH[NEtMe]₃); tris(diethylamino) silane (SiH[NEt₂]₃); tris(iso-propylamino) silane (SiH[NHiPr]₃, C₉H₂₅N₃Si, or TIPAS); tris(dimethylamino) silylamide (Si[NMe₂]₃[NH₂]); tetrakis(dimethylamino) silane (Si[NMe₂]₄); tetrakis(ethylmethylamino) silane (Si[NEtMe]₄); tetrakis(diethylamino) silane (Si[NEt₂]₄); 1,2-diethyl-tetrakis(diethylamino) disilane ([Et₂N]₂EtSi-SiEt[NEt₂]₂); 1,2-dimethyl-tetrakis(dimethylamino) disilane ([Me₂N]₂MeSi-SiMe[NMe₂]₂); 1,2-dimethyl-tetrakis(diethylamino)disilane ([Et₂N]₂MeSi-SiMe[NEt₂]₂); hexakis(methylamino)disilane ([MeHN]₃Si—Si[NHMe]₃); hexakis(ethylamino)disilane ([EtHN]₃Si—Si[NHEt]₃); hexakis(dimethylamino)disilazane (Me₂N—Si[NMe₂]₂—Si[NMe₂]₂—NMe₂), and the like.

In some embodiments, the silane precursor is a halosilane precursor. A halosilane precursor is defined as a precursor having at least one halogen-containing atom and at least one silicon atom. Halogens include chlorine, fluorine, bromine, and iodine. In some embodiments, the halosilane precursor includes a structure of formula (I):

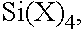

wherein at least one X includes a halogen atom.

For example, one halosilane is tetrachlorosilane or silicon tetrachloride (SiCl₄). Another example of a chemical formula of a halosilane is SiₙX_{y}H₂ where X is a halogen and H is hydrogen; n is an integer greater than or equal to 1 and is equal to the number of Si atoms in the molecule; in some embodiments, y is about 1 to about 4, and z is 4-y. Additional examples include but are not limited to SiHCl₃, SiH₂Cl₂, and SiH₃Cl.

Examples of halosilanes are iodosilanes, bromosilanes, chlorosilanes and fluorosilanes. Specific chlorosilanes include but are not limited to tetrachlorosilane, trichlorosilane, dichlorosilane (DCS), monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, hexachlorodisilane (HCDS), and the like.

In some embodiments, the halosilane is carbon-free. In some embodiments, the halosilane is an organic silicon-containing precursor.

In some embodiments, the halosilane precursor (e.g., in formula (I)) has at least one optionally substituted C₁₋₂ haloalkyl group. Non-limiting haloaliphatic groups include-CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; or —CH₂CX_{y}H_{3-y}, wherein y is 1, 2, or 3, and wherein each X is, independently, halo (F, Cl, Br, or I). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CCl₃), bromomethyl (—CH₂Br), dibromomethyl (—CHBr₂), tribromomethyl (—CBr₃), iodomethyl (—CH₂I), diiodomethyl (—CHI₂), triiodomethyl (—CI₃), bromofluoromethyl (—CHFBr), chlorofluoromethyl (—CHFCl), fluoroiodomethyl (—CHFI), 2-fluoroethyl (—CH₂CH_{2F}), 2-chloroethyl (—CH₂CH₂Cl), 2-bromoethyl (—CH₂CH₂Br), 2-iodoethyl (—CH₂CH₂I), 2,2-difluoroethyl (—CH₂CHF₂), 2,2-dichloroethyl (—CH₂CHCI₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes β-halo-substituted ethyl. Yet other haloaliphatic groups include C₁₋₄ haloalkyl, C₂₋₄ haloalkenyl, and C₂₋₄ haloalkynyl.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for processing substrates, the method comprising:
providing a substrate having a feature thereon;
exposing the substrate to a silicon-containing precursor in vapor phase for a duration sufficient to adsorb at least some of the silicon-containing precursor onto a surface of the substrate to form an adsorbed silicon-containing precursor;
exposing the substrate to a first nitrogen-containing gas in a plasma-free environment; and
exposing the substrate to a plasma generated from igniting a second nitrogen-containing gas to form silicon nitride on the surface of the substrate.

2. The method of claim 1, wherein the plasma comprises radical species selected from the group consisting of nitrogen radicals, hydrogen radicals, and nitrogen hydrogen radicals.

3. The method of claim 1, wherein at least one of exposing the substrate to the first nitrogen-containing gas in the plasma-free environment and exposing the substrate to the plasma generated from igniting the second nitrogen-containing gas further comprises exposing the substrate to hydrogen gas.

4. The method of claim 1, wherein the second nitrogen-containing gas comprises two or more gases.

5. The method of claim 1, wherein the silicon-containing precursor is a halogen-containing precursor.

6. The method of claim 1, wherein the plasma is generated remotely.

7. The method of claim 1, further comprising exposing the formed silicon nitride to an in-situ nitridation or oxidation process to incorporate nitrogen or oxygen to form a second silicon-containing film.

8. The method of claim 1, further comprising prior to providing the substrate having the feature thereon, setting a temperature of one or more chamber components of a process chamber used to house substrates to at least about 650° C.: after setting the temperature to at least about 650° C., introducing a halogen-free aminosilane precursor to the process chamber; and introducing a nitrogen-containing reactant and igniting a plasma to form a silicon nitride undercoat on at least one of the one or more chamber components.

9. A method for treating a process chamber having no substrate therein, the method comprising:
setting a temperature of one or more chamber components of the process chamber to at least about 650° C.;
after setting the temperature to at least about 650° C., introducing a halogen-free aminosilane precursor to the process chamber; and
introducing a nitrogen-containing reactant and igniting a plasma to form a silicon nitride undercoat on at least one of the one or more chamber components.

10. A method for processing substrates, the method comprising:
introducing a substrate having a feature;
exposing the substrate to a silicon-containing precursor for a duration sufficient to adsorb at least some silicon-containing precursor to a surface of the substrate;
exposing the substrate to a reactant species for forming a first silicon-containing film; and
exposing the first silicon-containing film to an in-situ nitridation or oxidation process to incorporate nitrogen or oxygen to form a second silicon-containing film.
